(19) United States
(12) Patent Application Publication
(10) Pub. No.: US 2023/0155074 A1
(43) Pub. Date: May 18, 2023

(54) RED LIGHT-EMITTING DIODE WITH PHOSPHIDE EPITAXIAL HETEROSTRUCTURE GROWN ON SILICON

(71) Applicant: Meta Platforms Technologies, LLC, Menlo Park, CA (US)

(72) Inventors: Pavel GORLACHUK, Cork (IE); Alexander TONKIKH, Wenzenbach (DE); Christopher PYNN, Redmond, WA (US)

(21) Appl. No.: 18/053,367

(22) Filed: Nov. 7, 2022

Related U.S. Application Data
(60) Provisional application No. 63/280,719, filed on Nov. 18, 2021.

(51) Int. Cl. H01L 33/50; H01L 33/00; H01L 33/06

(52) U.S. Cl. CPC H01L 33/502; H01L 33/005; H01L 33/06

(57) ABSTRACT

A red light-emitting micro-LED wafer includes a silicon substrate, a GaP buffer layer grown on the silicon substrate, a first doped (e.g., p-doped) GaP contact layer on the GaP buffer layer, an active region, and a second doped (e.g., n-doped) GaP contact layer on the active region. The active region includes a plurality of InGaP quantum barrier layers and one or more InGaAsP quantum well layers, where each of the one or more InGaAsP quantum well layers is sandwiched by two InGaP barrier layers of the plurality of InGaP barrier layers and is configured to emit red light. In some embodiments, the red light-emitting micro-LED wafer also includes a first doped AlGaP cladding layer between the first doped GaP contact layer and the active region, and a second doped AlGaP cladding layer between the second doped GaP contact layer and the active region.

### CROSS-REFERENCE TO RELATED APPLICATION

This application claims the benefit of and priority to U.S. Provisional Application No. 63/280,719, filed Nov. 18, 2021, entitled “RED LIGHT-EMITTING DIODE WITH PHOSPHIDE EPITAXIAL HETEROSTRUCTURE GROWN ON SILICON,” which is herein incorporated by reference in its entirety for all purposes.

### BACKGROUND

Light-emitting diodes (LEDs) convert electrical energy into optical energy, and offer many benefits over other light sources, such as reduced size, improved durability, and increased efficiency. LEDs can be used as light sources in many display systems, such as televisions, computer monitors, laptop computers, tablets, smartphones, projection systems, and wearable electronic devices. Micro-LEDs (“μLEDs”) based on III-V semiconductors, such as alloys of AlN, GaN, InN, InGaN, AlGaInP, other ternary and quaternary arsenide and phosphide alloys including GaInAsPN, AlGaInSb, and the like, have begun to be developed for various display applications due to their small size (e.g., with a linear dimension less than about 20 μm, less than about 10 μm, less than about 5 μm, or less than about 2 μm), high packing density (and hence higher resolution), and high brightness. For example, micro-LEDs that emit light of different colors (e.g., red, green, and blue) can be used to form the sub-pixels of a display system, such as a television or a near-eye display system.

### SUMMARY

This disclosure relates generally to light-emitting diodes (LEDs). More specifically, and without limitation, techniques disclosed herein relate to red light-emitting micro-LEDs including GaP-based epitaxial structures grown on a silicon substrate. Various inventive embodiments are described herein, including devices, systems, methods, materials, processes, and the like.

According to some embodiments, a semiconductor wafer includes a silicon substrate, a GaP buffer layer grown on the silicon substrate, a first doped (e.g., p-doped) GaP contact layer on the GaP buffer layer, an active region, and a second doped (e.g., n-doped) GaP contact layer on the active region. The active region includes a plurality of InGaP barrier layers, and one or more InGaAsP quantum well layers, where each of the one or more InGaAsP quantum well layers is sandwiched by two InGaP barrier layers of the plurality of InGaP barrier layers. In some embodiments, the silicon substrate may have a diameter greater than 6 inches, such as 8 inches or 12 inches.

In some embodiments, the semiconductor wafer also includes a first doped (e.g., p-doped) AlGaP cladding layer between the first doped GaP contact layer and the active region, and a second doped (e.g., n-doped) AlGaP cladding layer between the second doped GaP contact layer and the active region. In some embodiments, the first doped AlGaP cladding layer may be characterized by a composition of AlₓGa₁₋ₓP with 0<x≤0.5 and a thickness between about 50 and about 2000 nm, and the second doped AlGaP cladding layer may be characterized by a composition of AlₓGa₁₋ₓP with 0<x≤0.5 and a thickness between about 50 and about 2000 nm. In some embodiments, the semiconductor wafer also includes an etch-stop layer between the first doped GaP contact layer and the GaP buffer layer. The etch-stop layer is characterized by, for example, a composition of AlₓGa₁₋ₓP with 0<x≤0.5, a thickness between 0 and 1000 nm, and a dopant density between about 1×10¹⁸ and about 20×10¹⁸ cm⁻³, where the etch-stop layer may be p-doped or n-doped.

In some embodiments, the GaP buffer layer may be characterized by a thickness between about 100 and about 3000 nm, and a dopant density between about 1×10¹⁸ and about 20×10¹⁸ cm⁻³, where the GaP buffer layer may be p-doped with C, Mg, Zn, Be, or a combination thereof. In some embodiments, the first doped GaP contact layer may be characterized by a thickness between about 10 and about 500 nm and a dopant density between about 1×10¹⁹ and about 20×10¹⁹ cm⁻³, wherein the first doped GaP contact layer may be p-doped with C, Mg, Zn, Be, or a combination thereof. In some embodiments, the second doped GaP contact layer may be characterized by a thickness between about 10 and about 300 nm and a dopant density between about 5×10¹⁸ and about 50×10¹⁸ cm⁻³, where the second doped GaP contact layer may be n-doped with Si, S, Ge, Te, Se, or a combination thereof.

In some embodiments, each of the plurality of InGaP quantum barrier layers may be characterized by a composition of InₓGa₁₋ₓP with 0<x≤0.2, a thickness between 0 and about 500 nm, and undoped or doped with C, Mg, Zn, Be, Si, Ge, S, Se, Te, or a combination thereof at a dopant density between about 1×10¹⁶ and about 50×10¹⁶ cm⁻³. In some embodiments, each of the one or more InGaAsP quantum well layers may be characterized by a composition of InₓGa₁₋ₓAs_{y}P_{1-y} with 0<x≤0.55 and 0<y≤0.3, a thickness between about 2 and about 10 nm, and undoped or doped with C, Mg, Zn, Be, Si, Ge, S, Se, Te, or a combination thereof at a dopant density between about 1×10¹⁵ and about 50×10¹⁶ cm⁻³.

According to some embodiments, a light source may include a silicon substrate, a GaP buffer layer on the silicon substrate, and a plurality of mesa structures on the GaP buffer layer. Each of the plurality of mesa structures may include a first doped GaP contact layer on the GaP buffer layer, an active region, and a second doped GaP contact layer on the active region. The active region may include a plurality of InGaP quantum barrier layers and one or more InGaAsP quantum well layers, where each of the one or more InGaAsP quantum well layers may be sandwiched by two InGaP quantum barrier layers of the plurality of InGaP quantum barrier layers.

In some embodiments, each of the plurality of mesa structures may include a first doped AlGaP cladding layer between the first doped GaP contact layer and the active region, and a second doped AlGaP cladding layer between the second doped GaP contact layer and the active region. The first doped AlGaP cladding layer may be characterized by a composition of AlₓGa₁₋ₓP with 0<x≤0.5, and the second doped AlGaP cladding layer may be characterized by a composition of AlₓGa₁₋ₓP with 0<x≤0.5. In some embodiments, the light source may include an etch-stop layer between the GaP buffer layer and the first doped GaP contact layer of each of the plurality of mesa structures, the etch-stop layer characterized a composition of AlₓGa₁₋ₓP with 0<x≤0.5.

In some embodiments, each of the plurality of InGaP quantum barrier layers may be characterized by a composition of InₓGa₁₋ₓP with 0<x≤0.2 and a thickness between 0 and about 500 nm, and each of the one or more InGaAsP quantum well layers may be characterized by a composition of InₓGa₁₋ₓAs_{y}P_{1-y} with 0<x≤0.55 and 0<y≤0.3 and a thickness between about 2 and about 10 nm. The silicon substrate may have a diameter greater than 6 inches, such as about 8 inches or about 12 inches.

According to some embodiments, a micro-light emitting diode (micro-LED) device may include a silicon backplane including drive circuits formed thereon, and an array of micro-LEDs bonded to the silicon backplane. Each micro-LED of the array of micro-LEDs may include a first doped GaP contact layer, an active region, and a second doped GaP contact layer on the active region. The active region may include a plurality of InGaP quantum barrier layers, and one or more InGaAsP quantum well layers, where each of the one or more InGaAsP quantum well layers is sandwiched by two InGaP quantum barrier layers of the plurality of InGaP quantum barrier layers and is configured to emit red light.

In some embodiments of the micro-LED device, each of the plurality of InGaP quantum barrier layers may be characterized by a composition of InₓGa₁₋ₓP with 0<x≤0.2 and a thickness between 0 and about 500 nm, and each of the one or more InGaAsP quantum well layers may be characterized by a composition of InₓGa₁₋ₓAs_{y}P_{1-y} with 0<x≤0.55 and 0<y≤0.3 and a thickness between about 2 and about 10 nm. In some embodiments, the micro-LED device may include a first doped AlGaP cladding layer between the first doped GaP contact layer and the active region, and a second doped AlGaP cladding layer between the second doped GaP contact layer and the active region.

In some embodiments of the micro-LED device, the first doped GaP contact layer may be characterized by a thickness between about 10 and about 300 nm and a dopant density between about 5×10¹⁸ and about 50×10¹⁸ cm⁻³, where the first doped GaP contact layer may be n-doped with Si, S, Ge, Te, Se, or a combination thereof. The second doped GaP contact layer may be characterized by a thickness between about 10 and about 500 nm and a dopant density between about 1×10¹⁹ and about 20×10¹⁹ cm⁻³, where the second doped GaP contact layer may be p-doped with C, Mg, Zn, Be, or a combination thereof.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative embodiments are described in detail below with reference to the following figures.

FIG. 1 is a simplified block diagram of an example of an artificial reality system environment including a near-eye display according to certain embodiments.

FIG. 2 is a perspective view of an example of a near-eye display in the form of a head-mounted display (HMD) device for implementing some of the examples disclosed herein.

FIG. 3 is a perspective view of an example of a near-eye display in the form of a pair of glasses for implementing some of the examples disclosed herein.

FIG. 4 illustrates an example of an optical see-through augmented reality system including a waveguide display according to certain embodiments.

FIG. 5A illustrates an example of a near-eye display device including a waveguide display according to certain embodiments.

FIG. 5B illustrates an example of a near-eye display device including a waveguide display according to certain embodiments.

FIG. 6 illustrates an example of an image source assembly in an augmented reality system according to certain embodiments.

FIG. 7A illustrates an example of a light-emitting diode (LED) having a vertical mesa structure according to certain embodiments.

FIG. 7B is a cross-sectional view of an example of an LED having a parabolic mesa structure according to certain embodiments.

FIGS. 8A-8D illustrate an example of a method of hybrid bonding of an LED wafer to a backplane wafer according to certain embodiments.

FIG. 9 illustrates an example of an LED array including secondary optical components fabricated thereon according to certain embodiments.

FIG. 10A illustrates an example of a method of die-to-wafer bonding of an array of LEDs to a backplane wafer according to certain embodiments.

FIG. 10B illustrates an example of a method of wafer-to-wafer bonding of an LED wafer to a backplane wafer according to certain embodiments.

FIG. 11 includes a diagram illustrating bandgap energy levels, corresponding emission wavelengths, and lattice constants of semiconductor materials having different compositions.

FIG. 12 illustrates an example of a red light-emitting epitaxial structure on a micro-LED wafer according to certain embodiments.

FIGS. 13A-13D illustrate an example of a process of fabricating a micro-LED device according to certain embodiments.

FIGS. 14A-14F illustrate an example of a method of fabricating a micro-LED device using alignment-free metal-to-metal bonding and post-bonding mesa formation according to certain embodiments.

FIG. 15 includes a flowchart illustrating an example of a method of fabricating a micro-LED wafer including a GaP based epitaxially structure grown on a silicon substrate according to certain embodiments.

FIG. 16 is a simplified block diagram of an example of an electronic system of a near-eye display according to certain embodiments.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

This disclosure relates generally to light-emitting diodes (LEDs). More specifically, and without limitation, techniques disclosed herein relates to red light-emitting micro-LEDs including GaP-based epitaxial structures grown on a silicon substrate. Various inventive embodiments are described herein, including devices, systems, methods, materials, processes, and the like.

In LEDs, photons may be generated through the recombination of injected electrons and holes within an active region. LEDs with small pitches (e.g., less than about 10 μm, less than about 5 μm, less than about 3 μm, or less than about 2 μm) may be used in high-resolution display systems. For example, augmented reality (AR) and virtual reality (VR) applications may use near-eye displays that include tiny light emitters such as micro-LEDs. Micro-LEDs in high-resolution display systems may be controlled by drive circuits that can provide drive currents (and thus injected carriers) to the micro-LEDs based on pixel data of the display images, such that the micro-LEDs may emit light with desired intensities to form the display images. Micro-LEDs may be fabricated by epitaxially growing III-V semiconductor material layers on a growth substrate, whereas the drive circuits are generally fabricated on silicon wafers using CMOS processing technology developed for fabricating CMOS integrated circuits. The wafer that includes CMOS drive circuits fabricated thereon is often referred to as a backplane wafer or a CMOS backplane. Micro-LED arrays on a die or wafer may be bonded to the CMOS backplane, such that the individual micro-LEDs in the micro-LED arrays may be electrically connected to the corresponding pixel drive circuits and thus may become individually addressable to receive drive currents for driving the respective micro-LEDs. In some implementations, a thin-film transistor (TFT) circuit may be formed on the micro-LED wafer (or dies) or the CMOS backplane before the bonding. The bonded wafer stack may be diced to singulate individual devices that each include an array of micro-LEDs and the corresponding drive circuits.

Due to the small pitches of the micro-LED arrays and the small dimensions of individual micro-LEDs, it can be difficult to electrically connect the drive circuits to the electrodes of the LEDs using, for example, bonding wires, bonding bumps, and the like. In some implementations, the micro-LED arrays may be bonded face-to-face with the drive circuits using bonding pads on surfaces of the micro-LED arrays and bonding pads on the drive circuits, such that no routing wires may be needed and the interconnects between the micro-LEDs and the drive circuits can be short, which may enable high-density and high-performance bonding. However, it can be challenging to precisely align the bonding pads on the micro-LED arrays with the bonding pads on the drive circuits to form reliable bonding at the interfaces that may include both dielectric materials (e.g., SiO₂, SiN, or SiCN) and metal (e.g., Cu, Au, or Al) bonding pads. For example, when the pitch of the micro-LED device is about 2 to 4 microns or lower, the bonding pads may have a linear dimension less than about 1 μm in order to avoid shorting to adjacent micro-LEDs and to improve bonding strength of the dielectric bonding. The small bonding pads may be less tolerant to misalignments between the bonding pads, which may reduce the metal bonding area, increase the contact resistance (or may even result in an open circuit), and/or cause diffusion of metal atoms to the dielectric materials and the semiconductor materials. Thus, precise alignment of the bonding pads at the bonding surface of a micro-LED array and bonding pads at the bonding surface of a backplane wafer may be needed, which can be difficult to achieve using existing alignment and bonding techniques.

Lattice mismatch between the epitaxial layers and the growth substrate may cause strains in the epitaxial layers, which may cause bowing of the epitaxial layers and the growth substrate. For example, if GaN is used as the epitaxial material and sapphire is used as the growth substrate, the mismatch in the crystal lattices of GaN and sapphire may cause strain and bowing. As such, the micro-LED wafer may not be flat before the bonding, making it even more difficult to align and bond the micro-LED wafer to the CMOS backplane. For example, the bowing may change the lateral positions of alignment marks and may cause voids between the micro-LED wafer and the CMOS backplane, especially near the center of the wafer stack. These voids may cause defects in the LEDs. In some cases, an epitaxial layer grown with little or no strain (e.g., lattice matched to the growth substrate) at an elevated epitaxial growth temperature (e.g., greater than about 500° C.) may become strained at room temperature due to different coefficients of temperature expansion (CTEs) of the epitaxial layer and the substrate (e.g., GaAs substrate). In some cases, bonding a micro-LED wafer and a CMOS backplane at an elevated temperature may also cause bowing of the wafer stack due to different CTEs of the growth substrate (e.g., sapphire or GaAs substrate) of the micro-LED wafer and the substrate (e.g., silicon wafer) of the CMOS backplane. It can be challenging to match either the sapphire substrate or the GaAs substrates with state-of-the-art Si backplanes (e.g., on 12″ or 300-mm silicon wafer).

As such, there may be various reliability and yield issues caused by the CTE mismatch and crystal structure mismatch. For example, it can be challenging to reduce bowing and compensate for CTE mismatches between silicon and sapphire or GaAs. Therefore, it can be beneficial to grow epitaxial layers of micro-LEDs on Si substrates that have the same material and size as the silicon CMOS backplanes. GaN-based blue and green LEDs may be grown on silicon substrates, but GaN-based blue and green LEDs grown on silicon substrates may have a lower wall-plug efficiency than GaN-based blue and green LEDs grown on sapphire substrates, even though GaN epitaxial stacks grown on Si substrates can be very attractive for small micro-LEDs due to the relatively low difficulty in integration with CMOS backplanes.

GaN-based red light-emitting LEDs may generally have lower internal quantum efficiency than GaN-based blue and green LEDs. InGaAlP-based red light-emitting LEDs may have higher quantum efficiency, but gallium arsenide substrates for growing InGaAlP-based red light-emitting LEDs may be mostly available in wafers with diameters of about 4″ or 6″. This may limit the manufacture productivity and increase the cost. The material brittleness of GaAs wafers may also pose a risk for high-volume production. Furthermore, integrating red LEDs grown on GaAs substrates with silicon CMOS backplanes may also need thermal management improvement, for example, to reduce wafer bowing as described above. Thus, it may also be beneficial to grow red light-emitting epitaxial structures on silicon wafers. However, to achieve high-performance (e.g., high-efficiency) red micro-LEDs on silicon wafer, new heterostructure designs may be needed.

In some implementations, to overcome some of the above-described limitations (e.g., to reduce the number of de-bonding and bonding processes) and other limitations (e.g., internal electric field that may be caused by polarization-induced electric field and built-in depletion electric field and may contribute to Quantum-Confined Stark Effect (QCSE)), epitaxial structures of LEDs may be grown by growing n-type semiconductor layers after growing p-type semiconductor layers and the active layers (referred to as “n-side up”), rather than growing p-type semiconductor layers after growing the n-type semiconductor layers and the active layers (referred to as “p-side up”). However, to grow “n-side up” GaN epitaxial layers on sapphire or silicon substrates or grow “n-side up” InGaAlP epitaxial layers on GaAs or silicon substrates, the p-type contact layer may have greatly mismatched wide bandgaps, and thus may not be suitable for use as an intermediate layer between the growth substrate and the active region because it may cause the active region to become polycrystalline and decrease the recombination efficiency.

In addition, in red micro-LEDs made in InₓGa_{y}Al_{z}P_{0.5} epitaxial layers (where 0<x<0.5, 0≤y<0.5, 0≤z<0.5, and x+y+z=0.5) grown on GaAs substrates, the n-type semiconductor (e.g., InGaAlP or InAlP) layer, the InGaAlP/InGaP multiple quantum well layers, and the p-type semiconductor (e.g., InGaAlP or InAlP) layer may generally have in-plane compressive strain due to, for example, the difference between the lattice constant of the GaAs substrate and the lattice constant of the InₓGa_{y}Al_{z}P_{0.5} layers. Even though an InₓGa_{y}Al_{z}P_{0.5} epitaxial layers may be grown to have either compressive in-plane strain or tensile in-plane strain on a GaAs wafer, in some cases, an InₓGa_{y}Al_{z}P_{0.5} epitaxial layer grown with tensile strain or no strain (e.g., lattice matched to the GaAs substrate) may become compressive-strained at room temperature due to different coefficients of temperature expansion (CTEs) of the epitaxial layer and the GaAs substrate. Quantum well layers having in-plane compressive strain may increase the proportion of heavy holes and the effective mass of the holes, thereby reducing the mobility of the holes and the diffusion of the holes to the mesa sidewall regions that may cause non-radiative recombination at the mesa sidewall regions, and thus may improve the quantum efficiency of the micro-LEDs. However, the compressive strain in the epitaxial layers may cause a large bow of the wafer that includes the epitaxial layers grown thereon.

According to certain embodiments, a red micro-LED wafer may include GaP epitaxial structures grown on a silicon substrate, rather than a GaAs substrate. The GaP epitaxial structures may include in-plane lattice matched epitaxial layers because GaP materials may have lattice structures matching the lattice structure of silicon wafer. The GaP epitaxial structures may include indium-enriched InGaAsP quantum-well layers and an AlGaP etch stop layer. For example, the growth process may start with growing, on the silicon substrate, a GaAs buffer layer that closely matches the lattice structure of the silicon substrate. The subsequent layers may be grown using the same material (e.g., GaP) with the addition of Al and/or In for some layers. The active region may include quaternary materials (e.g., InGaAsP) that may emit red light. In some embodiments, the GaP epitaxial structures may be grown by growing the n-type epitaxial layers before growing the active layers and the p-type epitaxial layers in a “p-side up” epitaxial growing process. In some embodiments, the GaP epitaxial structures may be grown using modified doping strategies in “n-side up” epitaxial growing process.

In one example, a red light-emitting micro-LED wafer may include a silicon substrate, a p-GaP buffer layer grown on the silicon substrate, p-type GaP layers (e.g., a p-GaP contact layer and/or a p-AlGaP cladding layer) grown on the p-GaP buffer layer, InGaAsP/InGaP active layers grown on the p-type GaP layers, and n-type GaP layers (e.g., an n-AlGaP cladding layer and/or an n-GaP contact layer) grown on the active layers. The InGaAsP quantum-well layers may be direct-bandgap materials and may emit red light. The GaP base materials may have large bandgaps and thus may not absorb the emitted light (i.e., transparent to the emitted light).

Due to the larger lattice constant of InGaAsP than silicon and GaP, the InGaAsP quantum-well layers may have compressive strain. Due to the gradually changing lattice constant, the GaP-based layers (e.g., GaP contact layer, AlGaP cladding layer, and InGaP quantum barrier layers) grown before the InGaAsP quantum-well layers may have compressive strain, while the GaP-based layers (e.g., InGaP quantum barrier layers, AlGaP cladding layer, and GaP contact layer) grown after the InGaAsP quantum-well layers may have tensile strain. The tensile strain of some epitaxial layers may counter the compressive strain of other epitaxial layers, thereby reducing the net strain and the bow of the micro-LED wafer including the epitaxial layers. Due to the low bow of the micro-LED wafer, the bonding of the micro-LED wafer to a backplane may be easier, stronger, more accurate, and more reliable.

In addition, the strained epitaxial layers for strain balancing and bow reduction may result in an improvement in the efficiency of micro-LEDs at high operating current densities and elevated temperatures. For example, the tensile-strained semiconductor layers on the active region may lead to higher potential barrier. The increase in the height of the potential barrier may result in a lower leakage current and a higher wall plug efficiency (WPE) at elevated temperatures and/or high operating current densities.

Moreover, as described above, it may be easier to integrate LEDs grown on a silicon substrate with a CMOS backplane formed in a silicon substrate, and achieve reduced wafer bowing due to CTE matching between the two substrates. In addition, silicon substrates with diameters of 8 to 12 inches are readily available, while GaAs substrates may be limited to 4-6 inches in diameter (even though 8-inch GaAs substrates are being considered). Cost of Si substrates is also several times lower than that of GaAs substrates. Furthermore, growing heterostructures using the n-side-up growth process may decrease the number of subsequent processing steps (e.g., bonding to temporary wafer and de-bonding the temporary wafer) for fabrication of the micro-LEDs and bonding with the CMOS backplane. The processes disclosed herein may also allow unified fabrication processes with III-N-on-Si, where GaN-based blue and green light-emitting LEDs and GaP-based red light emitting LEDs may be grown on a same Si substrate to integrated micro-LEDs of different colors into a same wafer or a same die. The material system disclosed herein may also have significantly higher thermal conductivity, thereby providing a more stable thermal performance compared to other AlGaInP alloy material systems. Therefore, growing red light-emitting GaP-based LEDs on silicon wafers may improve the wafer integration, may be cost effective, may be more reliable, and may have higher efficiency, compared with red light-emitting LEDs grown on GaAs wafers.

The micro-LEDs described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some AR systems, the artificial images may be presented to users using an LED-based display subsystem.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

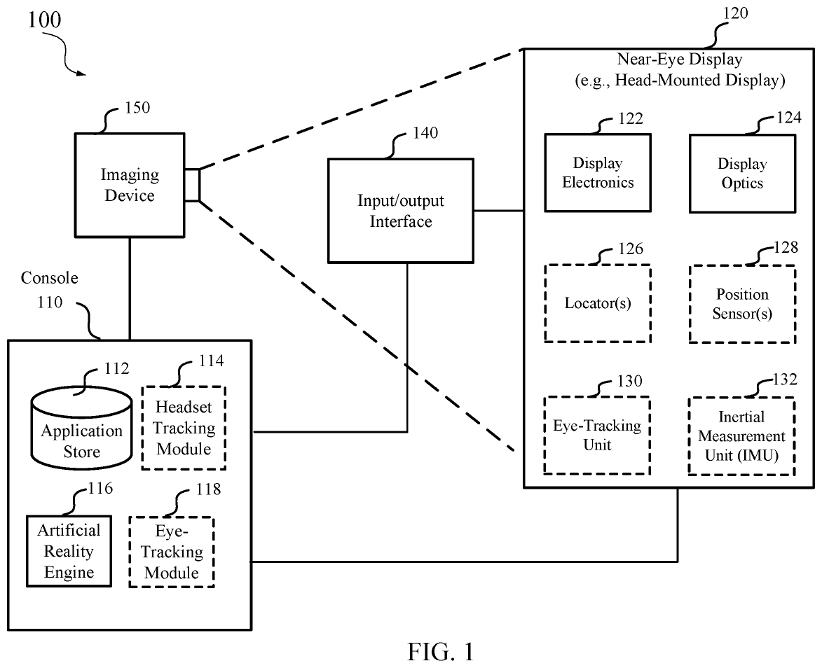

FIG. 1 is a simplified block diagram of an example of an artificial reality system environment 100 including a near-eye display 120 in accordance with certain embodiments. Artificial reality system environment 100 shown in FIG. 1 may include near-eye display 120, an optional external imaging device 150, and an optional input/output interface 140, each of which may be coupled to an optional console 110. While FIG. 1 shows an example of artificial reality system environment 100 including one near-eye display 120, one external imaging device 150, and one input/output interface 140, any number of these components may be included in artificial reality system environment 100, or any of the components may be omitted. For example, there may be multiple near-eye displays 120 monitored by one or more external imaging devices 150 in communication with console 110. In some configurations, artificial reality system environment 100 may not include external imaging device 150, optional input/output interface 140, and optional console 110. In alternative configurations, different or additional components may be included in artificial reality system environment 100.

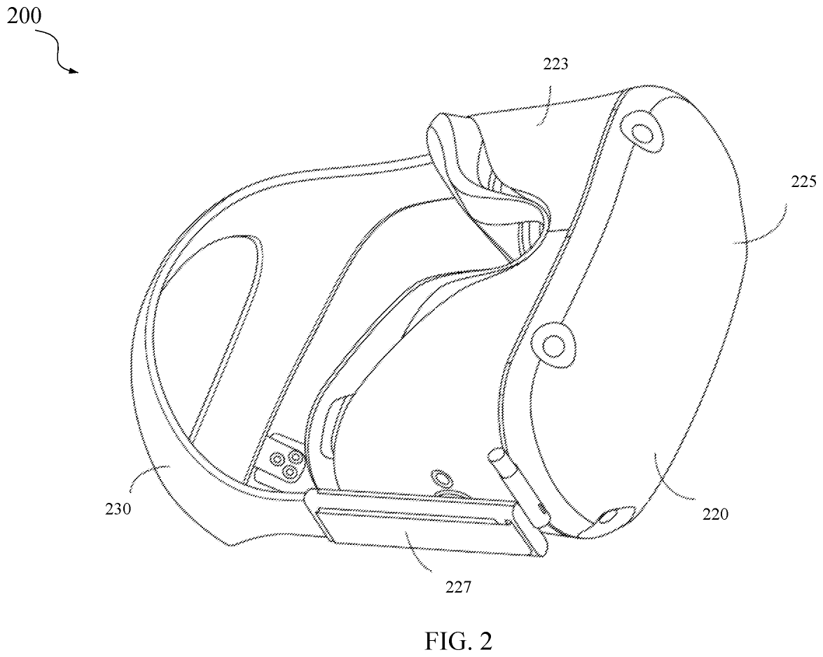

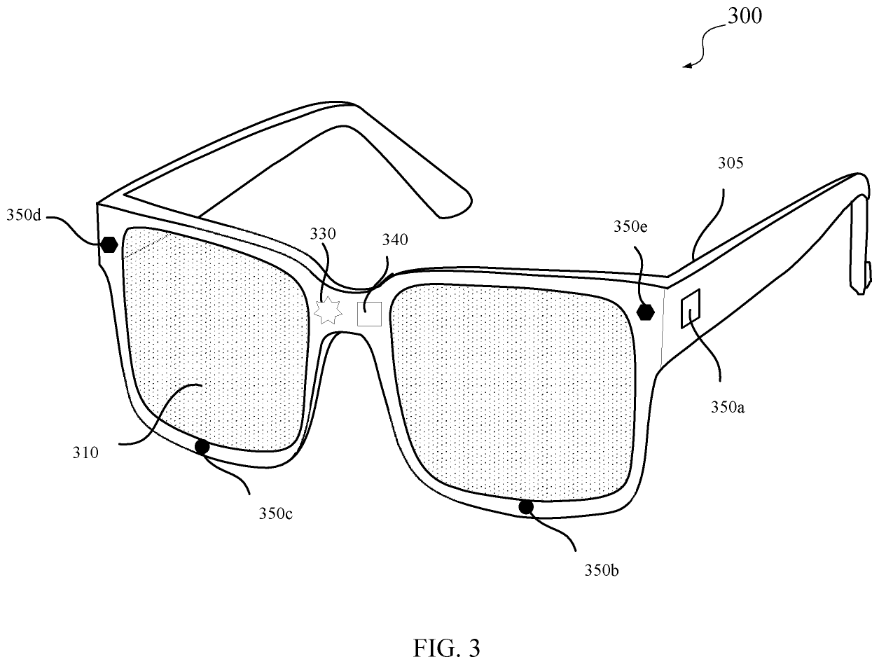

Near-eye display 120 may be a head-mounted display that presents content to a user. Examples of content presented by near-eye display 120 include one or more of images, videos, audio, or any combination thereof. In some embodiments, audio may be presented via an external device (e.g., speakers and/or headphones) that receives audio information from near-eye display 120, console 110, or both, and presents audio data based on the audio information. Near-eye display 120 may include one or more rigid bodies, which may be rigidly or non-rigidly coupled to each other. A rigid coupling between rigid bodies may cause the coupled rigid bodies to act as a single rigid entity. A non-rigid coupling between rigid bodies may allow the rigid bodies to move relative to each other. In various embodiments, near-eye display 120 may be implemented in any suitable form-factor, including a pair of glasses. Some embodiments of near-eye display 120 are further described below with respect to FIGS. 2 and 3. Additionally, in various embodiments, the functionality described herein may be used in a headset that combines images of an environment external to near-eye display 120 and artificial reality content (e.g., computer-generated images). Therefore, near-eye display 120 may augment images of a physical, real-world environment external to near-eye display 120 with generated content (e.g., images, video, sound, etc.) to present an augmented reality to a user.

In various embodiments, near-eye display 120 may include one or more of display electronics 122, display optics 124, and an eye-tracking unit 130. In some embodiments, near-eye display 120 may also include one or more locators 126, one or more position sensors 128, and an inertial measurement unit (IMU) 132. Near-eye display 120 may omit any of eye-tracking unit 130, locators 126, position sensors 128, and IMU 132, or include additional elements in various embodiments. Additionally, in some embodiments, near-eye display 120 may include elements combining the function of various elements described in conjunction with FIG. 1.

Display electronics 122 may display or facilitate the display of images to the user according to data received from, for example, console 110. In various embodiments, display electronics 122 may include one or more display panels, such as a liquid crystal display (LCD), an organic light-emitting diode (OLED) display, an inorganic light-emitting diode (ILED) display, a micro light-emitting diode (μLED) display, an active-matrix OLED display (AMOLED), a transparent OLED display (TOLED), or some other display. For example, in one implementation of near-eye display 120, display electronics 122 may include a front TOLED panel, a rear display panel, and an optical component (e.g., an attenuator, polarizer, or diffractive or spectral film) between the front and rear display panels. Display electronics 122 may include pixels to emit light of a predominant color such as red, green, blue, white, or yellow. In some implementations, display electronics 122 may display a three-dimensional (3D) image through stereoscopic effects produced by two-dimensional panels to create a subjective perception of image depth. For example, display electronics 122 may include a left display and a right display positioned in front of a user's left eye and right eye, respectively. The left and right displays may present copies of an image shifted horizontally relative to each other to create a stereoscopic effect (i.e., a perception of image depth by a user viewing the image).

In certain embodiments, display optics 124 may display image content optically (e.g., using optical waveguides and couplers) or magnify image light received from display electronics 122, correct optical errors associated with the image light, and present the corrected image light to a user of near-eye display 120. In various embodiments, display optics 124 may include one or more optical elements, such as, for example, a substrate, optical waveguides, an aperture, a Fresnel lens, a convex lens, a concave lens, a filter, input/output couplers, or any other suitable optical elements that may affect image light emitted from display electronics 122. Display optics 124 may include a combination of different optical elements as well as mechanical couplings to maintain relative spacing and orientation of the optical elements in the combination. One or more optical elements in display optics 124 may have an optical coating, such as an anti-reflective coating, a reflective coating, a filtering coating, or a combination of different optical coatings.

Magnification of the image light by display optics 124 may allow display electronics 122 to be physically smaller, weigh less, and consume less power than larger displays. Additionally, magnification may increase a field of view of the displayed content. The amount of magnification of image light by display optics 124 may be changed by adjusting, adding, or removing optical elements from display optics 124. In some embodiments, display optics 124 may project displayed images to one or more image planes that may be further away from the user's eyes than near-eye display 120.

Display optics 124 may also be designed to correct one or more types of optical errors, such as two-dimensional optical errors, three-dimensional optical errors, or any combination thereof. Two-dimensional errors may include optical aberrations that occur in two dimensions. Example types of two-dimensional errors may include barrel distortion, pincushion distortion, longitudinal chromatic aberration, and transverse chromatic aberration. Three-dimensional errors may include optical errors that occur in three dimensions. Example types of three-dimensional errors may include spherical aberration, comatic aberration, field curvature, and astigmatism.

Locators 126 may be objects located in specific positions on near-eye display 120 relative to one another and relative to a reference point on near-eye display 120. In some implementations, console 110 may identify locators 126 in images captured by external imaging device 150 to determine the artificial reality headset's position, orientation, or both. A locator 126 may be an LED, a corner cube reflector, a reflective marker, a type of light source that contrasts with an environment in which near-eye display 120 operates, or any combination thereof. In embodiments where locators 126 are active components (e.g., LEDs or other types of light emitting devices), locators 126 may emit light in the visible band (e.g., about 380 nm to 750 nm), in the infrared (IR) band (e.g., about 750 nm to 1 mm), in the ultraviolet band (e.g., about 10 nm to about 380 nm), in another portion of the electromagnetic spectrum, or in any combination of portions of the electromagnetic spectrum.

External imaging device 150 may include one or more cameras, one or more video cameras, any other device capable of capturing images including one or more of locators 126, or any combination thereof. Additionally, external imaging device 150 may include one or more filters (e.g., to increase signal to noise ratio). External imaging device 150 may be configured to detect light emitted or reflected from locators 126 in a field of view of external imaging device 150. In embodiments where locators 126 include passive elements (e.g., retroreflectors), external imaging device 150 may include a light source that illuminates some or all of locators 126, which may retro-reflect the light to the light source in external imaging device 150. Slow calibration data may be communicated from external imaging device 150 to console 110, and external imaging device 150 may receive one or more calibration parameters from console 110 to adjust one or more imaging parameters (e.g., focal length, focus, frame rate, sensor temperature, shutter speed, aperture, etc.).

Position sensors 128 may generate one or more measurement signals in response to motion of near-eye display 120. Examples of position sensors 128 may include accelerometers, gyroscopes, magnetometers, other motion-detecting or error-correcting sensors, or any combination thereof. For example, in some embodiments, position sensors 128 may include multiple accelerometers to measure translational motion (e.g., forward/back, up/down, or left/right) and multiple gyroscopes to measure rotational motion (e.g., pitch, yaw, or roll). In some embodiments, various position sensors may be oriented orthogonally to each other.

IMU 132 may be an electronic device that generates fast calibration data based on measurement signals received from one or more of position sensors 128. Position sensors 128 may be located external to IMU 132, internal to IMU 132, or any combination thereof. Based on the one or more measurement signals from one or more position sensors 128, IMU 132 may generate fast calibration data indicating an estimated position of near-eye display 120 relative to an initial position of near-eye display 120. For example, IMU 132 may integrate measurement signals received from accelerometers over time to estimate a velocity vector and integrate the velocity vector over time to determine an estimated position of a reference point on near-eye display 120. Alternatively, IMU 132 may provide the sampled measurement signals to console 110, which may determine the fast calibration data. While the reference point may generally be defined as a point in space, in various embodiments, the reference point may also be defined as a point within near-eye display 120 (e.g., a center of IMU 132).

Eye-tracking unit 130 may include one or more eye-tracking systems. Eye tracking may refer to determining an eye's position, including orientation and location of the eye, relative to near-eye display 120. An eye-tracking system may include an imaging system to image one or more eyes and may optionally include a light emitter, which may generate light that is directed to an eye such that light reflected by the eye may be captured by the imaging system. For example, eye-tracking unit 130 may include a non-coherent or coherent light source (e.g., a laser diode) emitting light in the visible spectrum or infrared spectrum, and a camera capturing the light reflected by the user's eye. As another example, eye-tracking unit 130 may capture reflected radio waves emitted by a miniature radar unit. Eye-tracking unit 130 may use low-power light emitters that emit light at frequencies and intensities that would not injure the eye or cause physical discomfort. Eye-tracking unit 130 may be arranged to increase contrast in images of an eye captured by eye-tracking unit 130 while reducing the overall power consumed by eye-tracking unit 130 (e.g., reducing power consumed by a light emitter and an imaging system included in eye-tracking unit 130). For example, in some implementations, eye-tracking unit 130 may consume less than 100 milliwatts of power.

Near-eye display 120 may use the orientation of the eye to, e.g., determine an inter-pupillary distance (IPD) of the user, determine gaze direction, introduce depth cues (e.g., blur image outside of the user's main line of sight), collect heuristics on the user interaction in the VR media (e.g., time spent on any particular subject, object, or frame as a function of exposed stimuli), some other functions that are based in part on the orientation of at least one of the user's eyes, or any combination thereof. Because the orientation may be determined for both eyes of the user, eye-tracking unit 130 may be able to determine where the user is looking. For example, determining a direction of a user's gaze may include determining a point of convergence based on the determined orientations of the user's left and right eyes. A point of convergence may be the point where the two foveal axes of the user's eyes intersect. The direction of the user's gaze may be the direction of a line passing through the point of convergence and the mid-point between the pupils of the user's eyes.

Input/output interface 140 may be a device that allows a user to send action requests to console 110. An action request may be a request to perform a particular action. For example, an action request may be to start or to end an application or to perform a particular action within the application. Input/output interface 140 may include one or more input devices. Example input devices may include a keyboard, a mouse, a game controller, a glove, a button, a touch screen, or any other suitable device for receiving action requests and communicating the received action requests to console 110. An action request received by the input/output interface 140 may be communicated to console 110, which may perform an action corresponding to the requested action. In some embodiments, input/output interface 140 may provide haptic feedback to the user in accordance with instructions received from console 110. For example, input/output interface 140 may provide haptic feedback when an action request is received, or when console 110 has performed a requested action and communicates instructions to input/output interface 140. In some embodiments, external imaging device 150 may be used to track input/output interface 140, such as tracking the location or position of a controller (which may include, for example, an IR light source) or a hand of the user to determine the motion of the user. In some embodiments, near-eye display 120 may include one or more imaging devices to track input/output interface 140, such as tracking the location or position of a controller or a hand of the user to determine the motion of the user.

Console 110 may provide content to near-eye display 120 for presentation to the user in accordance with information received from one or more of external imaging device 150, near-eye display 120, and input/output interface 140. In the example shown in FIG. 1, console 110 may include an application store 112, a headset tracking module 114, an artificial reality engine 116, and an eye-tracking module 118. Some embodiments of console 110 may include different or additional modules than those described in conjunction with FIG. 1. Functions further described below may be distributed among components of console 110 in a different manner than is described here.

In some embodiments, console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In various embodiments, the modules of console 110 described in conjunction with FIG. 1 may be encoded as instructions in the non-transitory computer-readable storage medium that, when executed by the processor, cause the processor to perform the functions further described below.

Application store 112 may store one or more applications for execution by console 110. An application may include a group of instructions that, when executed by a processor, generates content for presentation to the user. Content generated by an application may be in response to inputs received from the user via movement of the user's eyes or inputs received from the input/output interface 140. Examples of the applications may include gaming applications, conferencing applications, video playback application, or other suitable applications.

Headset tracking module 114 may track movements of near-eye display 120 using slow calibration information from external imaging device 150. For example, headset tracking module 114 may determine positions of a reference point of near-eye display 120 using observed locators from the slow calibration information and a model of near-eye display 120. Headset tracking module 114 may also determine positions of a reference point of near-eye display 120 using position information from the fast calibration information. Additionally, in some embodiments, headset tracking module 114 may use portions of the fast calibration information, the slow calibration information, or any combination thereof, to predict a future location of near-eye display 120. Headset tracking module 114 may provide the estimated or predicted future position of near-eye display 120 to artificial reality engine 116.

Artificial reality engine 116 may execute applications within artificial reality system environment 100 and receive position information of near-eye display 120, acceleration information of near-eye display 120, velocity information of near-eye display 120, predicted future positions of near-eye display 120, or any combination thereof from headset tracking module 114. Artificial reality engine 116 may also receive estimated eye position and orientation information from eye-tracking module 118. Based on the received information, artificial reality engine 116 may determine content to provide to near-eye display 120 for presentation to the user. For example, if the received information indicates that the user has looked to the left, artificial reality engine 116 may generate content for near-eye display 120 that mirrors the user's eye movement in a virtual environment. Additionally, artificial reality engine 116 may perform an action within an application executing on console 110 in response to an action request received from input/output interface 140, and provide feedback to the user indicating that the action has been performed. The feedback may be visual or audible feedback via near-eye display 120 or haptic feedback via input/output interface 140.

Eye-tracking module 118 may receive eye-tracking data from eye-tracking unit 130 and determine the position of the user's eye based on the eye tracking data. The position of the eye may include an eye's orientation, location, or both relative to near-eye display 120 or any element thereof. Because the eye's axes of rotation change as a function of the eye's location in its socket, determining the eye's location in its socket may allow eye-tracking module 118 to more accurately determine the eye's orientation.

FIG. 2 is a perspective view of an example of a near-eye display in the form of an HMD device 200 for implementing some of the examples disclosed herein. HMD device 200 may be a part of, e.g., a VR system, an AR system, an MR system, or any combination thereof. HMD device 200 may include a body 220 and a head strap 230. FIG. 2 shows a bottom side 223, a front side 225, and a left side 227 of body 220 in the perspective view. Head strap 230 may have an adjustable or extendible length. There may be a sufficient space between body 220 and head strap 230 of HMD device 200 for allowing a user to mount HMD device 200 onto the user's head. In various embodiments, HMD device 200 may include additional, fewer, or different components. For example, in some embodiments, HMD device 200 may include eyeglass temples and temple tips as shown in, for example, FIG. 3 below, rather than head strap 230.

HMD device 200 may present to a user media including virtual and/or augmented views of a physical, real-world environment with computer-generated elements. Examples of the media presented by HMD device 200 may include images (e.g., two-dimensional (2D) or three-dimensional (3D) images), videos (e.g., 2D or 3D videos), audio, or any combination thereof. The images and videos may be presented to each eye of the user by one or more display assemblies (not shown in FIG. 2) enclosed in body 220 of HMD device 200. In various embodiments, the one or more display assemblies may include a single electronic display panel or multiple electronic display panels (e.g., one display panel for each eye of the user). Examples of the electronic display panel(s) may include, for example, an LCD, an OLED display, an ILED display, a μLED display, an AMOLED, a TOLED, some other display, or any combination thereof. HMD device 200 may include two eye box regions.

In some implementations, HMD device 200 may include various sensors (not shown), such as depth sensors, motion sensors, position sensors, and eye tracking sensors. Some of these sensors may use a structured light pattern for sensing. In some implementations, HMD device 200 may include an input/output interface for communicating with a console. In some implementations, HMD device 200 may include a virtual reality engine (not shown) that can execute applications within HMD device 200 and receive depth information, position information, acceleration information, velocity information, predicted future positions, or any combination thereof of HMD device 200 from the various sensors. In some implementations, the information received by the virtual reality engine may be used for producing a signal (e.g., display instructions) to the one or more display assemblies. In some implementations, HMD device 200 may include locators (not shown, such as locators 126) located in fixed positions on body 220 relative to one another and relative to a reference point. Each of the locators may emit light that is detectable by an external imaging device.

FIG. 3 is a perspective view of an example of a near-eye display 300 in the form of a pair of glasses for implementing some of the examples disclosed herein. Near-eye display 300 may be a specific implementation of near-eye display 120 of FIG. 1, and may be configured to operate as a virtual reality display, an augmented reality display, and/or a mixed reality display. Near-eye display 300 may include a frame 305 and a display 310. Display 310 may be configured to present content to a user. In some embodiments, display 310 may include display electronics and/or display optics. For example, as described above with respect to near-eye display 120 of FIG. 1, display 310 may include an LCD display panel, an LED display panel, or an optical display panel (e.g., a waveguide display assembly).

Near-eye display 300 may further include various sensors 350a, 350b, 350c, 350d, and 350e on or within frame 305. In some embodiments, sensors 350a-350e may include one or more depth sensors, motion sensors, position sensors, inertial sensors, or ambient light sensors. In some embodiments, sensors 350a-350e may include one or more image sensors configured to generate image data representing different fields of views in different directions. In some embodiments, sensors 350a-350e may be used as input devices to control or influence the displayed content of near-eye display 300, and/or to provide an interactive VR/AR/MR experience to a user of near-eye display 300. In some embodiments, sensors 350a-350e may also be used for stereoscopic imaging.

In some embodiments, near-eye display 300 may further include one or more illuminators 330 to project light into the physical environment. The projected light may be associated with different frequency bands (e.g., visible light, infra-red light, ultra-violet light, etc.), and may serve various purposes. For example, illuminator(s) 330 may project light in a dark environment (or in an environment with low intensity of infra-red light, ultra-violet light, etc.) to assist sensors 350a-350e in capturing images of different objects within the dark environment. In some embodiments, illuminator(s) 330 may be used to project certain light patterns onto the objects within the environment. In some embodiments, illuminator(s) 330 may be used as locators, such as locators 126 described above with respect to FIG. 1.

In some embodiments, near-eye display 300 may also include a high-resolution camera 340. Camera 340 may capture images of the physical environment in the field of view. The captured images may be processed, for example, by a virtual reality engine (e.g., artificial reality engine 116 of FIG. 1) to add virtual objects to the captured images or modify physical objects in the captured images, and the processed images may be displayed to the user by display 310 for AR or MR applications.

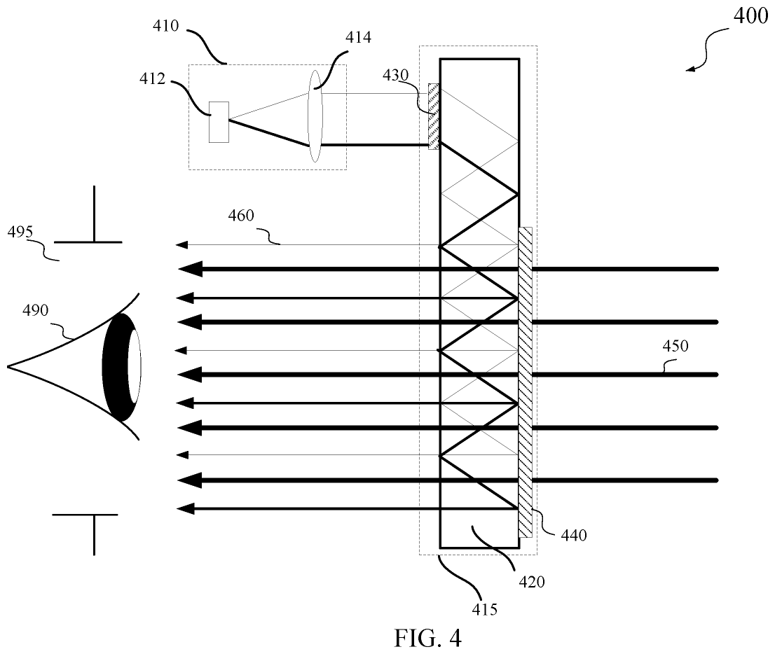

FIG. 4 illustrates an example of an optical see-through augmented reality system 400 including a waveguide display according to certain embodiments. Augmented reality system 400 may include a projector 410 and a combiner 415. Projector 410 may include a light source or image source 412 and projector optics 414. In some embodiments, light source or image source 412 may include one or more micro-LED devices described above. In some embodiments, image source 412 may include a plurality of pixels that displays virtual objects, such as an LCD display panel or an LED display panel. In some embodiments, image source 412 may include a light source that generates coherent or partially coherent light. For example, image source 412 may include a laser diode, a vertical cavity surface emitting laser, an LED, and/or a micro-LED described above. In some embodiments, image source 412 may include a plurality of light sources (e.g., an array of micro-LEDs described above), each emitting a monochromatic image light corresponding to a primary color (e.g., red, green, or blue). In some embodiments, image source 412 may include three two-dimensional arrays of micro-LEDs, where each two-dimensional array of micro-LEDs may include micro-LEDs configured to emit light of a primary color (e.g., red, green, or blue). In some embodiments, image source 412 may include an optical pattern generator, such as a spatial light modulator. Projector optics 414 may include one or more optical components that can condition the light from image source 412, such as expanding, collimating, scanning, or projecting light from image source 412 to combiner 415. The one or more optical components may include, for example, one or more lenses, liquid lenses, mirrors, apertures, and/or gratings. For example, in some embodiments, image source 412 may include one or more one-dimensional arrays or elongated two-dimensional arrays of micro-LEDs, and projector optics 414 may include one or more one-dimensional scanners (e.g., micro-mirrors or prisms) configured to scan the one-dimensional arrays or elongated two-dimensional arrays of micro-LEDs to generate image frames. In some embodiments, projector optics 414 may include a liquid lens (e.g., a liquid crystal lens) with a plurality of electrodes that allows scanning of the light from image source 412.

Combiner 415 may include an input coupler 430 for coupling light from projector 410 into a substrate 420 of combiner 415. Combiner 415 may transmit at least 50% of light in a first wavelength range and reflect at least 25% of light in a second wavelength range. For example, the first wavelength range may be visible light from about 400 nm to about 650 nm, and the second wavelength range may be in the infrared band, for example, from about 800 nm to about 1000 nm. Input coupler 430 may include a volume holographic grating, a diffractive optical element (DOE) (e.g., a surface-relief grating), a slanted surface of substrate 420, or a refractive coupler (e.g., a wedge or a prism). For example, input coupler 430 may include a reflective volume Bragg grating or a transmissive volume Bragg grating. Input coupler 430 may have a coupling efficiency of greater than 30%, 50%, 75%, 90%, or higher for visible light. Light coupled into substrate 420 may propagate within substrate 420 through, for example, total internal reflection (TIR). Substrate 420 may be in the form of a lens of a pair of eyeglasses. Substrate 420 may have a flat or a curved surface, and may include one or more types of dielectric materials, such as glass, quartz, plastic, polymer, poly(methyl methacrylate) (PMMA), crystal, or ceramic. A thickness of the substrate may range from, for example, less than about 1 mm to about 10 mm or more. Substrate 420 may be transparent to visible light.

Substrate 420 may include or may be coupled to a plurality of output couplers 440, each configured to extract at least a portion of the light guided by and propagating within substrate 420 from substrate 420, and direct extracted light 460 to an eyebox 495 where an eye 490 of the user of augmented reality system 400 may be located when augmented reality system 400 is in use. The plurality of output couplers 440 may replicate the exit pupil to increase the size of eyebox 495 such that the displayed image is visible in a larger area. As input coupler 430, output couplers 440 may include grating couplers (e.g., volume holographic gratings or surface-relief gratings), other diffraction optical elements (DOEs), prisms, etc. For example, output couplers 440 may include reflective volume Bragg gratings or transmissive volume Bragg gratings. Output couplers 440 may have different coupling (e.g., diffraction) efficiencies at different locations. Substrate 420 may also allow light 450 from the environment in front of combiner 415 to pass through with little or no loss. Output couplers 440 may also allow light 450 to pass through with little loss. For example, in some implementations, output couplers 440 may have a very low diffraction efficiency for light 450 such that light 450 may be refracted or otherwise pass through output couplers 440 with little loss, and thus may have a higher intensity than extracted light 460. In some implementations, output couplers 440 may have a high diffraction efficiency for light 450 and may diffract light 450 in certain desired directions (i.e., diffraction angles) with little loss. As a result, the user may be able to view combined images of the environment in front of combiner 415 and images of virtual objects projected by projector 410.

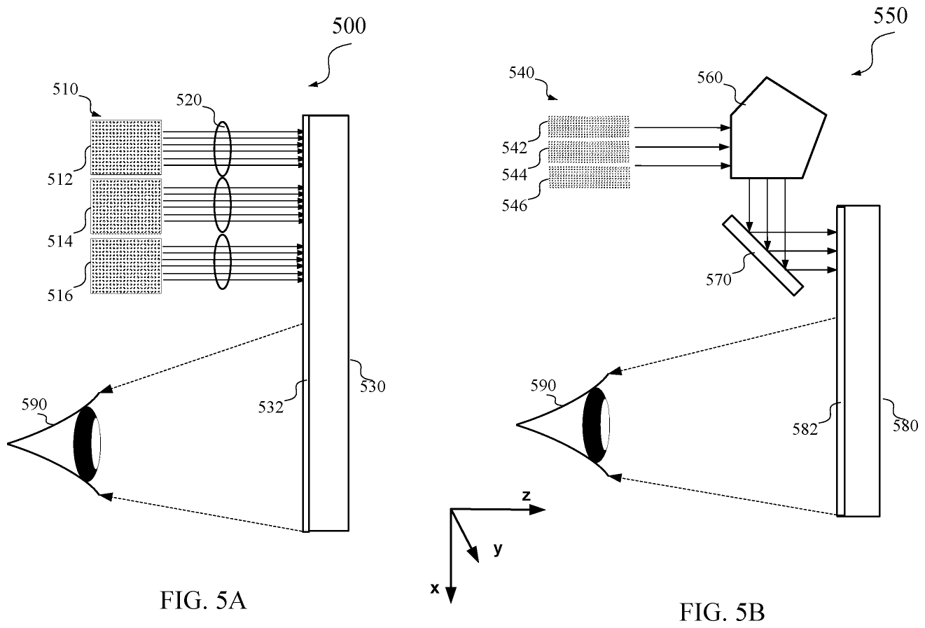

FIG. 5A illustrates an example of a near-eye display (NED) device 500 including a waveguide display 530 according to certain embodiments. NED device 500 may be an example of near-eye display 120, augmented reality system 400, or another type of display device. NED device 500 may include a light source 510, projection optics 520, and waveguide display 530. Light source 510 may include multiple panels of light emitters for different colors, such as a panel of red light emitters 512, a panel of green light emitters 514, and a panel of blue light emitters 516. The red light emitters 512 are organized into an array; the green light emitters 514 are organized into an array; and the blue light emitters 516 are organized into an array. The dimensions and pitches of light emitters in light source 510 may be small. For example, each light emitter may have a diameter less than 2 μm (e.g., about 1.2 μm) and the pitch may be less than 2 μm (e.g., about 1.5 μm). As such, the number of light emitters in each red light emitters 512, green light emitters 514, and blue light emitters 516 can be equal to or greater than the number of pixels in a display image, such as 960×720, 1280×720, 1440×1080, 1920×1080, 2160×1080, or 2560×1080 pixels. Thus, a display image may be generated simultaneously by light source 510. A scanning element may not be used in NED device 500.

Before reaching waveguide display 530, the light emitted by light source 510 may be conditioned by projection optics 520, which may include a lens array. Projection optics 520 may collimate or focus the light emitted by light source 510 to waveguide display 530, which may include a coupler 532 for coupling the light emitted by light source 510 into waveguide display 530. The light coupled into waveguide display 530 may propagate within waveguide display 530 through, for example, total internal reflection as described above with respect to FIG. 4. Coupler 532 may also couple portions of the light propagating within waveguide display 530 out of waveguide display 530 and towards user's eye 590.

FIG. 5B illustrates an example of a near-eye display (NED) device 550 including a waveguide display 580 according to certain embodiments. In some embodiments, NED device 550 may use a scanning mirror 570 to project light from a light source 540 to an image field where a user's eye 590 may be located. NED device 550 may be an example of near-eye display 120, augmented reality system 400, or another type of display device. Light source 540 may include one or more rows or one or more columns of light emitters of different colors, such as multiple rows of red light emitters 542, multiple rows of green light emitters 544, and multiple rows of blue light emitters 546. For example, red light emitters 542, green light emitters 544, and blue light emitters 546 may each include N rows, each row including, for example, 2560 light emitters (pixels). The red light emitters 542 are organized into an array; the green light emitters 544 are organized into an array; and the blue light emitters 546 are organized into an array. In some embodiments, light source 540 may include a single line of light emitters for each color. In some embodiments, light source 540 may include multiple columns of light emitters for each of red, green, and blue colors, where each column may include, for example, 1080 light emitters. In some embodiments, the dimensions and/or pitches of the light emitters in light source 540 may be relatively large (e.g., about 3-5 μm) and thus light source 540 may not include sufficient light emitters for simultaneously generating a full display image. For example, the number of light emitters for a single color may be fewer than the number of pixels (e.g., 2560×1080 pixels) in a display image. The light emitted by light source 540 may be a set of collimated or diverging beams of light.

Before reaching scanning mirror 570, the light emitted by light source 540 may be conditioned by various optical devices, such as collimating lenses or a freeform optical element 560. Freeform optical element 560 may include, for example, a multi-facet prism or another light folding element that may direct the light emitted by light source 540 towards scanning mirror 570, such as changing the propagation direction of the light emitted by light source 540 by, for example, about 90° or larger. In some embodiments, freeform optical element 560 may be rotatable to scan the light. Scanning mirror 570 and/or freeform optical element 560 may reflect and project the light emitted by light source 540 to waveguide display 580, which may include a coupler 582 for coupling the light emitted by light source 540 into waveguide display 580. The light coupled into waveguide display 580 may propagate within waveguide display 580 through, for example, total internal reflection as described above with respect to FIG. 4. Coupler 582 may also couple portions of the light propagating within waveguide display 580 out of waveguide display 580 and towards user's eye 590.

Scanning mirror 570 may include a microelectromechanical system (MEMS) mirror or any other suitable mirrors. Scanning mirror 570 may rotate to scan in one or two dimensions. As scanning mirror 570 rotates, the light emitted by light source 540 may be directed to a different area of waveguide display 580 such that a full display image may be projected onto waveguide display 580 and directed to user's eye 590 by waveguide display 580 in each scanning cycle. For example, in embodiments where light source 540 includes light emitters for all pixels in one or more rows or columns, scanning mirror 570 may be rotated in the column or row direction (e.g., x or y direction) to scan an image. In embodiments where light source 540 includes light emitters for some but not all pixels in one or more rows or columns, scanning mirror 570 may be rotated in both the row and column directions (e.g., both x and y directions) to project a display image (e.g., using a raster-type scanning pattern).

NED device 550 may operate in predefined display periods. A display period (e.g., display cycle) may refer to a duration of time in which a full image is scanned or projected. For example, a display period may be a reciprocal of the desired frame rate. In NED device 550 that includes scanning mirror 570, the display period may also be referred to as a scanning period or scanning cycle. The light generation by light source 540 may be synchronized with the rotation of scanning mirror 570. For example, each scanning cycle may include multiple scanning steps, where light source 540 may generate a different light pattern in each respective scanning step.

In each scanning cycle, as scanning mirror 570 rotates, a display image may be projected onto waveguide display 580 and user's eye 590. The actual color value and light intensity (e.g., brightness) of a given pixel location of the display image may be an average of the light beams of the three colors (e.g., red, green, and blue) illuminating the pixel location during the scanning period. After completing a scanning period, scanning mirror 570 may revert back to the initial position to project light for the first few rows of the next display image or may rotate in a reverse direction or scan pattern to project light for the next display image, where a new set of driving signals may be fed to light source 540. The same process may be repeated as scanning mirror 570 rotates in each scanning cycle. As such, different images may be projected to user's eye 590 in different scanning cycles.

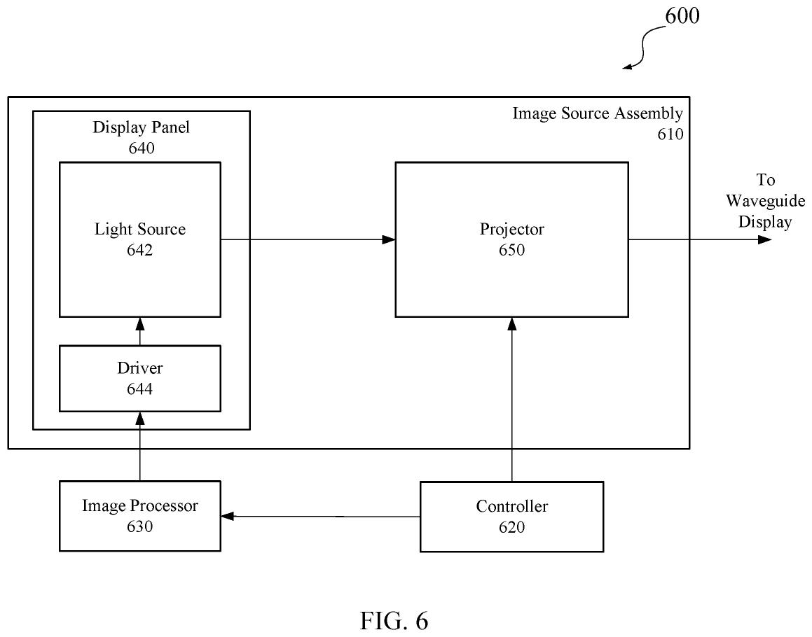

FIG. 6 illustrates an example of an image source assembly 610 in a near-eye display system 600 according to certain embodiments. Image source assembly 610 may include, for example, a display panel 640 that may generate display images to be projected to the user's eyes, and a projector 650 that may project the display images generated by display panel 640 to a waveguide display as described above with respect to FIGS. 4-5B. Display panel 640 may include a light source 642 and a drive circuit 644 for light source 642. Light source 642 may include, for example, light source 510 or 540. Projector 650 may include, for example, freeform optical element 560, scanning mirror 570, and/or projection optics 520 described above. Near-eye display system 600 may also include a controller 620 that synchronously controls light source 642 and projector 650 (e.g., scanning mirror 570). Image source assembly 610 may generate and output an image light to a waveguide display (not shown in FIG. 6), such as waveguide display 530 or 580. As described above, the waveguide display may receive the image light at one or more input-coupling elements, and guide the received image light to one or more output-coupling elements. The input and output coupling elements may include, for example, a diffraction grating, a holographic grating, a prism, or any combination thereof. The input-coupling element may be chosen such that total internal reflection occurs with the waveguide display. The output-coupling element may couple portions of the total internally reflected image light out of the waveguide display.

As described above, light source 642 may include a plurality of light emitters arranged in an array or a matrix. Each light emitter may emit monochromatic light, such as red light, blue light, green light, infra-red light, and the like. While RGB colors are often discussed in this disclosure, embodiments described herein are not limited to using red, green, and blue as primary colors. Other colors can also be used as the primary colors of near-eye display system 600. In some embodiments, a display panel in accordance with an embodiment may use more than three primary colors. Each pixel in light source 642 may include three subpixels that include a red micro-LED, a green micro-LED, and a blue micro-LED. A semiconductor LED generally includes an active light emitting layer within multiple layers of semiconductor materials. The multiple layers of semiconductor materials may include different compound materials or a same base material with different dopants and/or different doping densities. For example, the multiple layers of semiconductor materials may include an n-type material layer, an active region that may include hetero-structures (e.g., one or more quantum wells), and a p-type material layer. The multiple layers of semiconductor materials may be grown on a surface of a substrate having a certain orientation. In some embodiments, to increase light extraction efficiency, a mesa that includes at least some of the layers of semiconductor materials may be formed.

Controller 620 may control the image rendering operations of image source assembly 610, such as the operations of light source 642 and/or projector 650. For example, controller 620 may determine instructions for image source assembly 610 to render one or more display images. The instructions may include display instructions and scanning instructions. In some embodiments, the display instructions may include an image file (e.g., a bitmap file). The display instructions may be received from, for example, a console, such as console 110 described above with respect to FIG. 1. The scanning instructions may be used by image source assembly 610 to generate image light. The scanning instructions may specify, for example, a type of a source of image light (e.g., monochromatic or polychromatic), a scanning rate, an orientation of a scanning apparatus, one or more illumination parameters, or any combination thereof. Controller 620 may include a combination of hardware, software, and/or firmware not shown here so as not to obscure other aspects of the present disclosure.

In some embodiments, controller 620 may be a graphics processing unit (GPU) of a display device. In other embodiments, controller 620 may be other kinds of processors. The operations performed by controller 620 may include taking content for display and dividing the content into discrete sections. Controller 620 may provide to light source 642 scanning instructions that include an address corresponding to an individual source element of light source 642 and/or an electrical bias applied to the individual source element. Controller 620 may instruct light source 642 to sequentially present the discrete sections using light emitters corresponding to one or more rows of pixels in an image ultimately displayed to the user. Controller 620 may also instruct projector 650 to perform different adjustments of the light. For example, controller 620 may control projector 650 to scan the discrete sections to different areas of a coupling element of the waveguide display (e.g., waveguide display 580) as described above with respect to FIG. 5B. As such, at the exit pupil of the waveguide display, each discrete portion is presented in a different respective location. While each discrete section is presented at a different respective time, the presentation and scanning of the discrete sections occur fast enough such that a user's eye may integrate the different sections into a single image or series of images.

Image processor 630 may be a general-purpose processor and/or one or more application-specific circuits that are dedicated to performing the features described herein. In one embodiment, a general-purpose processor may be coupled to a memory to execute software instructions that cause the processor to perform certain processes described herein. In another embodiment, image processor 630 may be one or more circuits that are dedicated to performing certain features. While image processor 630 in FIG. 6 is shown as a stand-alone unit that is separate from controller 620 and drive circuit 644, image processor 630 may be a sub-unit of controller 620 or drive circuit 644 in other embodiments. In other words, in those embodiments, controller 620 or drive circuit 644 may perform various image processing functions of image processor 630. Image processor 630 may also be referred to as an image processing circuit.

In the example shown in FIG. 6, light source 642 may be driven by drive circuit 644, based on data or instructions (e.g., display and scanning instructions) sent from controller 620 or image processor 630. In one embodiment, drive circuit 644 may include a circuit panel that connects to and mechanically holds various light emitters of light source 642. Light source 642 may emit light in accordance with one or more illumination parameters that are set by the controller 620 and potentially adjusted by image processor 630 and drive circuit 644. An illumination parameter may be used by light source 642 to generate light. An illumination parameter may include, for example, source wavelength, pulse rate, pulse amplitude, beam type (continuous or pulsed), other parameter(s) that may affect the emitted light, or any combination thereof. In some embodiments, the source light generated by light source 642 may include multiple beams of red light, green light, and blue light, or any combination thereof.

Projector 650 may perform a set of optical functions, such as focusing, combining, conditioning, or scanning the image light generated by light source 642. In some embodiments, projector 650 may include a combining assembly, a light conditioning assembly, or a scanning mirror assembly. Projector 650 may include one or more optical components that optically adjust and potentially re-direct the light from light source 642. One example of the adjustment of light may include conditioning the light, such as expanding, collimating, correcting for one or more optical errors (e.g., field curvature, chromatic aberration, etc.), some other adjustments of the light, or any combination thereof. The optical components of projector 650 may include, for example, lenses, mirrors, apertures, gratings, or any combination thereof.

Projector 650 may redirect image light via its one or more reflective and/or refractive portions so that the image light is projected at certain orientations toward the waveguide display. The location where the image light is redirected toward the waveguide display may depend on specific orientations of the one or more reflective and/or refractive portions. In some embodiments, projector 650 includes a single scanning mirror that scans in at least two dimensions. In other embodiments, projector 650 may include a plurality of scanning mirrors that each scan in directions orthogonal to each other. Projector 650 may perform a raster scan (horizontally or vertically), a bi-resonant scan, or any combination thereof. In some embodiments, projector 650 may perform a controlled vibration along the horizontal and/or vertical directions with a specific frequency of oscillation to scan along two dimensions and generate a two-dimensional projected image of the media presented to user's eyes. In other embodiments, projector 650 may include a lens or prism that may serve similar or the same function as one or more scanning mirrors. In some embodiments, image source assembly 610 may not include a projector, where the light emitted by light source 642 may be directly incident on the waveguide display.

In semiconductor LEDs, photons are usually generated at a certain internal quantum efficiency through the recombination of electrons and holes within an active region (e.g., one or more semiconductor layers), where the internal quantum efficiency is the proportion of the radiative electron-hole recombination in the active region that emits photons. The generated light may then be extracted from the LEDs in a particular direction or within a particular solid angle. The ratio between the number of emitted photons extracted from an LED and the number of electrons passing through the LED is referred to as the external quantum efficiency, which describes how efficiently the LED converts injected electrons to photons that are extracted from the device.

The external quantum efficiency may be proportional to the injection efficiency, the internal quantum efficiency, and the extraction efficiency. The injection efficiency refers to the proportion of electrons passing through the device that are injected into the active region. The extraction efficiency is the proportion of photons generated in the active region that escape from the device. For LEDs, and in particular, micro-LEDs with reduced physical dimensions, improving the internal and external quantum efficiency and/or controlling the emission spectrum may be challenging. In some embodiments, to increase the light extraction efficiency, a mesa that includes at least some of the layers of semiconductor materials may be formed.

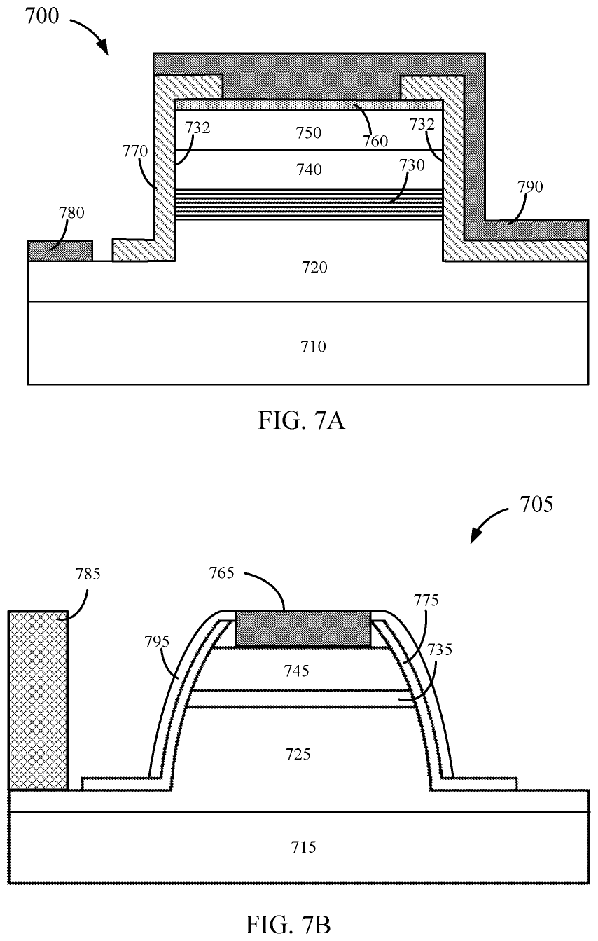

FIG. 7A illustrates an example of an LED 700 having a vertical mesa structure. LED 700 may be a light emitter in light source 510, 540, or 642. LED 700 may be a micro-LED made of inorganic materials, such as multiple layers of semiconductor materials. The layered semiconductor light emitting device may include multiple layers of III-V semiconductor materials. A III-V semiconductor material may include one or more Group III elements, such as aluminum (Al), gallium (Ga), or indium (In), in combination with a Group V element, such as nitrogen (N), phosphorus (P), arsenic (As), or antimony (Sb). When the Group V element of the III-V semiconductor material includes nitrogen, the III-V semiconductor material is referred to as a III-nitride material. The layered semiconductor light emitting device may be manufactured by growing multiple epitaxial layers on a substrate using techniques such as vapor-phase epitaxy (VPE), liquid-phase epitaxy (LPE), molecular beam epitaxy (MBE), or metalorganic chemical vapor deposition (MOCVD). For example, the layers of the semiconductor materials may be grown layer-by-layer on a substrate with a certain crystal lattice orientation (e.g., polar, nonpolar, or semi-polar orientation), such as a GaN, GaAs, or GaP substrate, or a substrate including, but not limited to, sapphire, silicon carbide, silicon, zinc oxide, boron nitride, lithium aluminate, lithium niobate, germanium, aluminum nitride, lithium gallate, partially substituted spinels, or quaternary tetragonal oxides sharing the beta-LiAlO₂ structure, where the substrate may be cut in a specific direction to expose a specific plane as the growth surface.

In the example shown in FIG. 7A, LED 700 may include a substrate 710, which may include, for example, a sapphire substrate or a GaN substrate. A semiconductor layer 720 may be grown on substrate 710. Semiconductor layer 720 may include a III-V material, such as GaN, and may be p-doped (e.g., with Mg, Ca, Zn, or Be) or n-doped (e.g., with Si or Ge). One or more active layers 730 may be grown on semiconductor layer 720 to form an active region. Active layer 730 may include III-V materials, such as one or more InGaN layers, one or more AlInGaP layers, and/or one or more GaN layers, which may form one or more heterostructures, such as one or more quantum wells or MQWs. A semiconductor layer 740 may be grown on active layer 730. Semiconductor layer 740 may include a III-V material, such as GaN, and may be p-doped (e.g., with Mg, Ca, Zn, or Be) or n-doped (e.g., with Si or Ge). One of semiconductor layer 720 and semiconductor layer 740 may be a p-type layer and the other one may be an n-type layer. Semiconductor layer 720 and semiconductor layer 740 sandwich active layer 730 to form the light emitting region. For example, LED 700 may include a layer of InGaN situated between a layer of p-type GaN doped with magnesium and a layer of n-type GaN doped with silicon or oxygen. In some embodiments, LED 700 may include a layer of AlInGaP situated between a layer of p-type AlInGaP doped with zinc or magnesium and a layer of n-type AlInGaP doped with selenium, silicon, or tellurium.

In some embodiments, an electron-blocking layer (EBL) (not shown in FIG. 7A) may be grown to form a layer between active layer 730 and at least one of semiconductor layer 720 or semiconductor layer 740. The EBL may reduce the electron leakage current and improve the efficiency of the LED. In some embodiments, a heavily-doped semiconductor layer 750, such as a P⁺ or P⁺⁺ semiconductor layer, may be formed on semiconductor layer 740 and act as a contact layer for forming an ohmic contact and reducing the contact impedance of the device. In some embodiments, a conductive layer 760 may be formed on heavily-doped semiconductor layer 750. Conductive layer 760 may include, for example, an indium tin oxide (ITO) or Al/Ni/Au film. In one example, conductive layer 760 may include a transparent ITO layer.

To make contact with semiconductor layer 720 (e.g., an n-GaN layer) and to more efficiently extract light emitted by active layer 730 from LED 700, the semiconductor material layers (including heavily-doped semiconductor layer 750, semiconductor layer 740, active layer 730, and semiconductor layer 720) may be etched to expose semiconductor layer 720 and to form a mesa structure that includes layers 720-760. The mesa structure may confine the carriers within the device. Etching the mesa structure may lead to the formation of mesa sidewalls 732 that may be orthogonal to the growth planes. A passivation layer 770 may be formed on sidewalls 732 of the mesa structure. Passivation layer 770 may include an oxide layer, such as a SiO₂ layer, and may act as a reflector to reflect emitted light out of LED 700. A contact layer 780, which may include a metal layer, such as Al, Au, Ni, Ti, or any combination thereof, may be formed on semiconductor layer 720 and may act as an electrode of LED 700. In addition, another contact layer 790, such as an Al/Ni/Au metal layer, may be formed on conductive layer 760 and may act as another electrode of LED 700.

When a voltage signal is applied to contact layers 780 and 790, electrons and holes may recombine in active layer 730, where the recombination of electrons and holes may cause photon emission. The wavelength and energy of the emitted photons may depend on the energy bandgap between the valence band and the conduction band in active layer 730. For example, InGaN active layers may emit green or blue light, AlGaN active layers may emit blue to ultraviolet light, while AlInGaP active layers may emit red, orange, yellow, or green light. The emitted photons may be reflected by passivation layer 770 and may exit LED 700 from the top (e.g., conductive layer 760 and contact layer 790) or bottom (e.g., substrate 710).

In some embodiments, LED 700 may include one or more other components, such as a lens, on the light emission surface, such as substrate 710, to focus or collimate the emitted light or couple the emitted light into a waveguide. In some embodiments, an LED may include a mesa of another shape, such as planar, conical, semi-parabolic, or parabolic, and a base area of the mesa may be circular, rectangular, hexagonal, or triangular. For example, the LED may include a mesa of a curved shape (e.g., paraboloid shape) and/or a non-curved shape (e.g., conic shape). The mesa may be truncated or non-truncated.

FIG. 7B is a cross-sectional view of an example of an LED 705 having a parabolic mesa structure. Similar to LED 700, LED 705 may include multiple layers of semiconductor materials, such as multiple layers of III-V semiconductor materials. The semiconductor material layers may be epitaxially grown on a substrate 715, such as a GaN substrate or a sapphire substrate. For example, a semiconductor layer 725 may be grown on substrate 715. Semiconductor layer 725 may include a III-V material, such as GaN, and may be p-doped (e.g., with Mg, Ca, Zn, or Be) or n-doped (e.g., with Si or Ge). One or more active layer 735 may be grown on semiconductor layer 725. Active layer 735 may include III-V materials, such as one or more InGaN layers, one or more AlInGaP layers, and/or one or more GaN layers, which may form one or more heterostructures, such as one or more quantum wells. A semiconductor layer 745 may be grown on active layer 735. Semiconductor layer 745 may include a III-V material, such as GaN, and may be p-doped (e.g., with Mg, Ca, Zn, or Be) or n-doped (e.g., with Si or Ge). One of semiconductor layer 725 and semiconductor layer 745 may be a p-type layer and the other one may be an n-type layer.

To make contact with semiconductor layer 725 (e.g., an n-type GaN layer) and to more efficiently extract light emitted by active layer 735 from LED 705, the semiconductor layers may be etched to expose semiconductor layer 725 and to form a mesa structure that includes layers 725-745. The mesa structure may confine carriers within the injection area of the device. Etching the mesa structure may lead to the formation of mesa side walls (also referred to herein as facets) that may be non-parallel with, or in some cases, orthogonal, to the growth planes associated with crystalline growth of layers 725-745.

As shown in FIG. 7B, LED 705 may have a mesa structure that includes a flat top. A dielectric layer 775 (e.g., SiO₂ or SiNx) may be formed on the facets of the mesa structure. In some embodiments, dielectric layer 775 may include multiple layers of dielectric materials. In some embodiments, a metal layer 795 may be formed on dielectric layer 775. Metal layer 795 may include one or more metal or metal alloy materials, such as aluminum (Al), silver (Ag), gold (Au), platinum (Pt), titanium (Ti), copper (Cu), or any combination thereof. Dielectric layer 775 and metal layer 795 may form a mesa reflector that can reflect light emitted by active layer 735 toward substrate 715. In some embodiments, the mesa reflector may be parabolic-shaped to act as a parabolic reflector that may at least partially collimate the emitted light.

Electrical contact 765 and electrical contact 785 may be formed on semiconductor layer 745 and semiconductor layer 725, respectively, to act as electrodes. Electrical contact 765 and electrical contact 785 may each include a conductive material, such as Al, Au, Pt, Ag, Ni, Ti, Cu, or any combination thereof (e.g., Ag/Pt/Au or Al/Ni/Au), and may act as the electrodes of LED 705. In the example shown in FIG. 7B, electrical contact 785 may be an n-contact, and electrical contact 765 may be a p-contact. Electrical contact 765 and semiconductor layer 745 (e.g., a p-type semiconductor layer) may form a back reflector for reflecting light emitted by active layer 735 back toward substrate 715. In some embodiments, electrical contact 765 and metal layer 795 include same material(s) and can be formed using the same processes. In some embodiments, an additional conductive layer (not shown) may be included as an intermediate conductive layer between the electrical contacts 765 and 785 and the semiconductor layers.

When a voltage signal is applied across contacts 765 and 785, electrons and holes may recombine in active layer 735. The recombination of electrons and holes may cause photon emission, thus producing light. The wavelength and energy of the emitted photons may depend on the energy bandgap between the valence band and the conduction band in active layer 735. For example, InGaN active layers may emit green or blue light, while AlInGaP active layers may emit red, orange, yellow, or green light. The emitted photons may propagate in many different directions, and may be reflected by the mesa reflector and/or the back reflector and may exit LED 705, for example, from the bottom side (e.g., substrate 715) shown in FIG. 7B. One or more other secondary optical components, such as a lens or a grating, may be formed on the light emission surface, such as substrate 715, to focus or collimate the emitted light and/or couple the emitted light into a waveguide.

One or two-dimensional arrays of the LEDs described above may be manufactured on a wafer to form light sources (e.g., light source 642). Driver circuits (e.g., drive circuit 644) may be fabricated, for example, on a silicon wafer using CMOS processes. The LEDs and the drive circuits on wafers may be diced and then bonded together, or may be bonded on the wafer level and then diced. Various bonding techniques can be used for bonding the LEDs and the drive circuits, such as adhesive bonding, metal-to-metal bonding, metal oxide bonding, wafer-to-wafer bonding, die-to-wafer bonding, hybrid bonding, and the like.

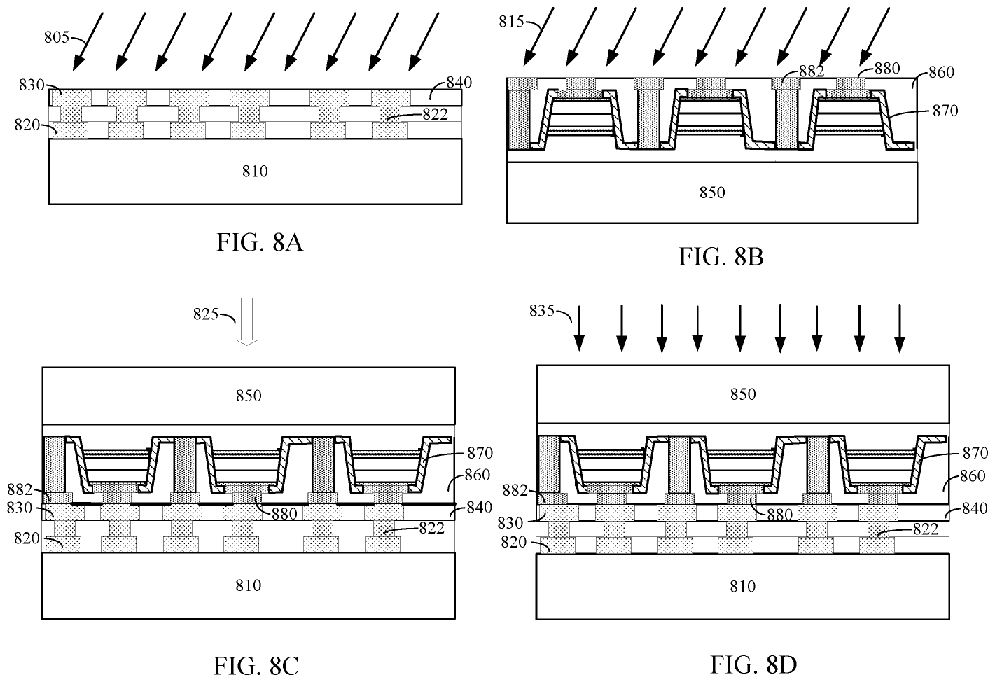

FIGS. 8A-8D illustrate an example of a method of hybrid bonding of an LED wafer to a backplane wafer according to certain embodiments. The hybrid bonding may generally include wafer cleaning and activation, high-precision alignment of contacts of one wafer with contacts of another wafer, dielectric bonding of dielectric materials at the surfaces of the wafers at room temperature, and metal bonding of the contacts by annealing at elevated temperatures. FIG. 8A shows a substrate 810 with passive or active circuits 820 manufactured thereon. As described above with respect to FIGS. 8A-8B, substrate 810 may include, for example, a silicon wafer. Circuits 820 may include drive circuits for the arrays of LEDs. A bonding layer may include dielectric regions 840 and contact pads 830 connected to circuits 820 through electrical interconnects 822. Contact pads 830 may include, for example, Cu, Ag, Au, Al, W, Mo, Ni, Ti, Pt, Pd, or the like. Dielectric materials in dielectric regions 840 may include SiCN, SiO₂, SiN, Al₂O₃, HfO₂, ZrO₂, Ta₂O₅, or the like. The bonding layer may be planarized and polished using, for example, chemical mechanical polishing, where the planarization or polishing may cause dishing (a bowl like profile) in the contact pads. The surfaces of the bonding layers may be cleaned and activated by, for example, an ion (e.g., plasma) or fast atom (e.g., Ar) beam 805. The activated surface may be atomically clean and may be reactive for formation of direct bonds between wafers when they are brought into contact, for example, at room temperature.

FIG. 8B illustrates a wafer 850 including an array of micro-LEDs 870 fabricated thereon as described above with respect to, for example, FIGS. 7A-8B. Wafer 850 may be a carrier wafer and may include, for example, GaAs, InP, GaN, AlN, sapphire, SiC, Si, or the like. Micro-LEDs 870 may include an n-type layer, an active region, and a p-type layer epitaxially grown on wafer 850. The epitaxial layers may include various III-V semiconductor materials described above, and may be processed from the p-type layer side to etch mesa structures in the epitaxial layers, such as substantially vertical structures, parabolic structures, conic structures, or the like. Passivation layers and/or reflection layers may be formed on the sidewalls of the mesa structures. P-contacts 880 and n-contacts 882 may be formed in a dielectric material layer 860 deposited on the mesa structures and may make electrical contacts with the p-type layer and the n-type layers, respectively. Dielectric materials in dielectric material layer 860 may include, for example, SiCN, SiO₂, SiN, Al₂O₃, HfO₂, ZrO₂, Ta₂O₅, or the like. P-contacts 880 and n-contacts 882 may include, for example, Cu, Ag, Au, Al, W, Mo, Ni, Ti, Pt, Pd, or the like. The top surfaces of p-contacts 880, n-contacts 882, and dielectric material layer 860 may form a bonding layer. The bonding layer may be planarized and polished using, for example, chemical mechanical polishing, where the polishing may cause dishing in p-contacts 880 and n-contacts 882. The bonding layer may then be cleaned and activated by, for example, an ion (e.g., plasma) or fast atom (e.g., Ar) beam 815. The activated surface may be atomically clean and reactive for formation of direct bonds between wafers when they are brought into contact, for example, at room temperature.

FIG. 8C illustrates a room temperature bonding process for bonding the dielectric materials in the bonding layers. For example, after the bonding layer that includes dielectric regions 840 and contact pads 830 and the bonding layer that includes p-contacts 880, n-contacts 882, and dielectric material layer 860 are surface activated, wafer 850 and micro-LEDs 870 may be turned upside down and brought into contact with substrate 810 and the circuits formed thereon. In some embodiments, compression pressure 825 may be applied to substrate 810 and wafer 850 such that the bonding layers are pressed against each other. Due to the surface activation and the dishing in the contacts, dielectric regions 840 and dielectric material layer 860 may be in direct contact because of the surface attractive force, and may react and form chemical bonds between them because the surface atoms may have dangling bonds and may be in unstable energy states after the activation. Thus, the dielectric materials in dielectric regions 840 and dielectric material layer 860 may be bonded together with or without heat treatment or pressure.

FIG. 8D illustrates an annealing process for bonding the contacts in the bonding layers after bonding the dielectric materials in the bonding layers. For example, contact pads 830 and p-contacts 880 or n-contacts 882 may be bonded together by annealing at, for example, about 200-400° C. or higher. During the annealing process, heat 835 may cause the contacts to expand more than the dielectric materials (due to different coefficients of thermal expansion), and thus may close the dishing gaps between the contacts such that contact pads 830 and p-contacts 880 or n-contacts 882 may be in contact and may form direct metallic bonds at the activated surfaces.

In some embodiments, after the micro-LEDs are bonded to the drive circuits, the substrate on which the micro-LEDs are fabricated may be thinned or removed, and various secondary optical components may be fabricated on the light emitting surfaces of the micro-LEDs to, for example, extract, collimate, and redirect the light emitted from the active regions of the micro-LEDs. In one example, micro-lenses may be formed on the micro-LEDs, where each micro-lens may correspond to a respective micro-LED and may help to improve the light extraction efficiency and collimate the light emitted by the micro-LED. In some embodiments, the secondary optical components may be fabricated in the substrate or the n-type layer of the micro-LEDs. In some embodiments, the secondary optical components may be fabricated in a dielectric layer deposited on the n-type side of the micro-LEDs. Examples of the secondary optical components may include a lens, a grating, an antireflection (AR) coating, a prism, a photonic crystal, or the like.

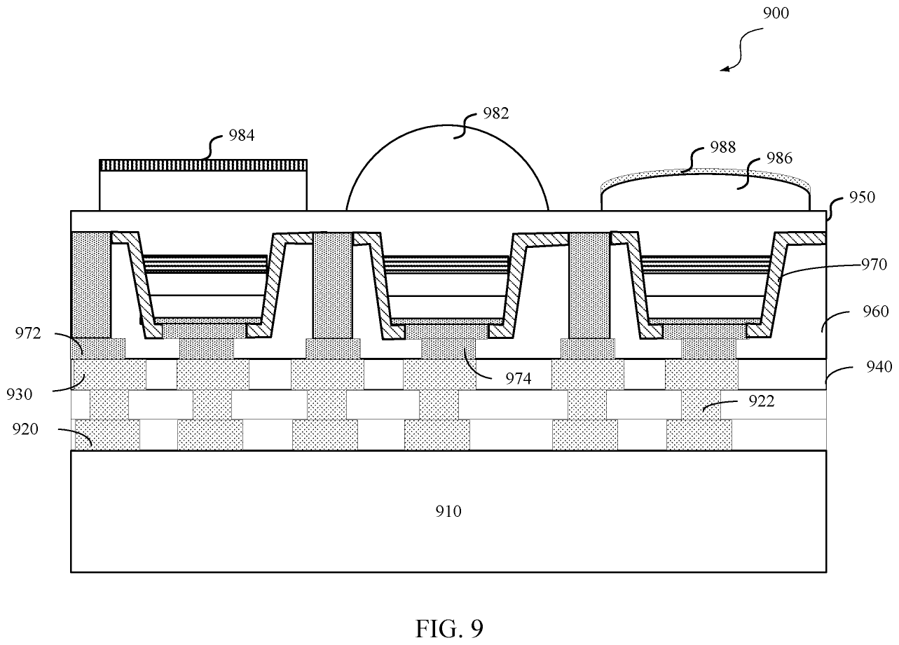

FIG. 9 illustrates an example of an LED array 900 including secondary optical components fabricated thereon according to certain embodiments. LED array 900 may be made by bonding an LED chip or wafer with a silicon wafer including electrical circuits fabricated thereon, using any suitable bonding techniques described above with respect to, for example, FIGS. 8A-9D. In the example shown in FIG. 9, LED array 900 may be bonded using a wafer-to-wafer hybrid bonding technique as described above with respect to FIG. 9A-9D. LED array 900 may include a substrate 910, which may be, for example, a silicon wafer. Integrated circuits 920, such as LED drive circuits, may be fabricated on substrate 910. Integrated circuits 920 may be connected to p-contacts 974 and n-contacts 972 of micro-LEDs 970 through interconnects 922 and contact pads 930, where contact pads 930 may form metallic bonds with p-contacts 974 and n-contacts 972. Dielectric layer 940 on substrate 910 may be bonded to dielectric layer 960 through fusion bonding.

The substrate (not shown) of the LED chip or wafer may be thinned or may be removed to expose the n-type layer 950 of micro-LEDs 970. Various secondary optical components, such as a spherical micro-lens 982, a grating 984, a micro-lens 986, an antireflection layer 988, and the like, may be formed in or on top of n-type layer 950. For example, spherical micro-lens arrays may be etched in the semiconductor materials of micro-LEDs 970 using a gray-scale mask and a photoresist with a linear response to exposure light, or using an etch mask formed by thermal reflowing of a patterned photoresist layer. The secondary optical components may also be etched in a dielectric layer deposited on n-type layer 950 using similar photolithographic techniques or other techniques. For example, micro-lens arrays may be formed in a polymer layer through thermal reflowing of the polymer layer that is patterned using a binary mask. The micro-lens arrays in the polymer layer may be used as the secondary optical components or may be used as the etch mask for transferring the profiles of the micro-lens arrays into a dielectric layer or a semiconductor layer. The dielectric layer may include, for example, SiCN, SiO₂, SiN, Al₂O₃, HfO₂, ZrO₂, Ta₂O₅, or the like. In some embodiments, a micro-LED 970 may have multiple corresponding secondary optical components, such as a micro-lens and an anti-reflection coating, a micro-lens etched in the semiconductor material and a micro-lens etched in a dielectric material layer, a micro-lens and a grating, a spherical lens and an aspherical lens, and the like. Three different secondary optical components are illustrated in FIG. 9 to show some examples of secondary optical components that can be formed on micro-LEDs 970, which does not necessary imply that different secondary optical components are used simultaneously for every LED array.

For micro-LED devices with small pitches (e.g., less than about 5 μm, 3 μm, or 2 μm), in order to have sufficiently large areas for strong dielectric bonding of the oxide-oxide interfaces at room temperature, the metal bonding pads may need to be small, such as about one quarter, one third, or one half of the total bond interface area. Precise alignment of the metal bonding pads may be needed to make good electrical connections between the bonding pads. In some embodiments where the two bonded wafers include materials having different coefficients of thermal expansion (CTEs), the dielectric materials bonded at room temperature may help to reduce or prevent misalignment of the contact pads caused by the different thermal expansions. In some embodiments, to further reduce or avoid the misalignment of the contact pads at a high temperature during annealing, trenches may be formed between micro-LEDs, between groups of micro-LEDs, through part or all of the substrate, or the like, before bonding.

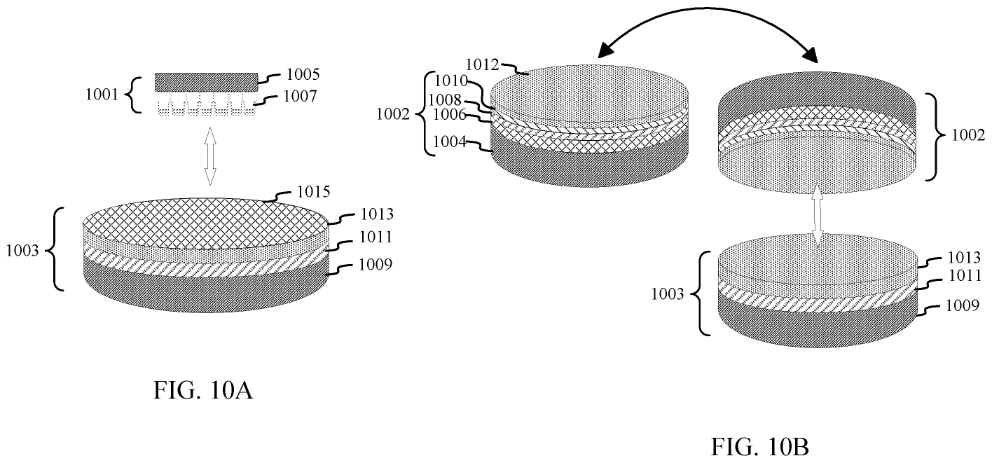

FIG. 10A illustrates an example of a method of die-to-wafer bonding of an array of LEDs to a backplane wafer according to certain embodiments. In the example shown in FIG. 10A, an LED array 1001 may include a plurality of LEDs 1007 on a carrier substrate 1005. Carrier substrate 1005 may include various materials, such as GaAs, InP, GaN, AlN, sapphire, SiC, Si, or the like. LEDs 1007 may be fabricated by, for example, growing various epitaxial layers, forming mesa structures, and forming electrical contacts or electrodes, before performing the bonding. The epitaxial layers may include various materials, such as GaN, InGaN, (AlGaIn)P, (AlGaIn)AsP, (AlGaIn)AsN, (Eu:InGa)N, (AlGaIn)N, or the like, and may include an n-type layer, a p-type layer, and an active layer that includes one or more heterostructures, such as one or more quantum wells or MQWs. The electrical contacts may include various conductive materials, such as a metal or a metal alloy.

A wafer 1003 may include a base layer 1009 having passive or active integrated circuits (e.g., drive circuits 1011) fabricated thereon. Base layer 1009 may include, for example, a silicon wafer. Driver circuits 1011 may be used to control the operations of LEDs 1007. For example, the drive circuit for each LED 1007 may include a 2T1C pixel structure that has two transistors and one capacitor. Wafer 1003 may also include a bonding layer 1013. Bonding layer 1013 may include various materials, such as a metal, an oxide, a dielectric, CuSn, AuTi, and the like. In some embodiments, a patterned layer 1015 may be formed on a surface of bonding layer 1013, where patterned layer 1015 may include a metallic grid made of a conductive material, such as Cu, Ag, Au, Al, or the like.

LED array 1001 may be bonded to wafer 1003 via bonding layer 1013 or patterned layer 1015. For example, patterned layer 1015 may include metal pads or bumps made of various materials, such as CuSn, AuSn, or nanoporous Au, that may be used to align LEDs 1007 of LED array 1001 with corresponding drive circuits 1011 on wafer 1003. In one example, LED array 1001 may be brought toward wafer 1003 until LEDs 1007 come into contact with respective metal pads or bumps corresponding to drive circuits 1011. Some or all of LEDs 1007 may be aligned with drive circuits 1011, and may then be bonded to wafer 1003 via patterned layer 1015 by various bonding techniques, such as metal-to-metal bonding. After LEDs 1007 have been bonded to wafer 1003, carrier substrate 1005 may be removed from LEDs 1007.

For high-resolution micro-LED display panel, due to the small pitches of the micro-LED array and the small dimensions of individual micro-LEDs, it can be challenging to electrically connect the drive circuits to the electrodes of the LEDs. For example, in the face-to-face bonding techniques describe above, it is difficult to precisely align the bonding pads on the micro-LED devices with the bonding pads on the drive circuits and form reliable bonding at the interfaces that may include both dielectric materials (e.g., SiO₂, SiN, or SiCN) and metal (e.g., Cu, Au, or Al) bonding pads. In particular, when the pitch of the micro-LED device is about 2 or 3 microns or lower, the bonding pads may have a linear dimension less than about 1 μm in order to avoid shorting to adjacent micro-LEDs and to improve bonding strength for the dielectric bonding. However, small bonding pads may be less tolerant to misalignments between the bonding pads, which may reduce the metal bonding area, increase the contact resistance (or may even be an open circuit), and/or cause diffusion of metals to the dielectric materials and the semiconductor materials. Thus, precise alignment of the bonding pads on surfaces of the micro-LED arrays and bonding pads on surfaces of CMOS backplane may be needed in the conventional processes. However, the accuracy of die-to-wafer or wafer-to-wafer bonding alignment using state-of-art equipment may be on the order of about 0.5 μm or about 1 μm, which may not be adequate for bonding the small-pitch micro-LED arrays (e.g., with a linear dimension of the bonding pads on the order of 1 μm or shorter) to CMOS drive circuits.

In some implementations, to avoid precise alignment for the bonding, a micro-LED wafer may be bonded to a CMOS backplane after the epitaxial layer growth and before the formation of individual micro-LED on the micro-LED wafer, where the micro-LED wafer and the CMOS backplane may be bonded through metal-to-metal bonding of two solid metal bonding layers on the two wafers. No alignment would be needed to bond the solid contiguous metal bonding layers. After the bonding, the epitaxial layers on the micro-LED wafer and the metal bonding layers may be etched to form individual micro-LEDs. The etching process may have much higher alignment accuracy and thus may form individual micro-LEDs that align with the underlying pixel drive circuits.

FIG. 10B illustrates an example of a method of wafer-to-wafer of an LED wafer to a backplane wafer according to certain embodiments. As shown in FIG. 10B, a first wafer 1002 may include a substrate 1004, a first semiconductor layer 1006, active layers 1008, and a second semiconductor layer 1010. Substrate 1004 may include various materials, such as GaAs, InP, GaN, AlN, sapphire, SiC, Si, or the like. First semiconductor layer 1006, active layers 1008, and second semiconductor layer 1010 may include various semiconductor materials, such as GaN, InGaN, (AlGaIn)P, (AlGaIn)AsP, (AlGaIn)AsN, (Eu:InGa)N, (AlGaIn)N, or the like. In some embodiments, first semiconductor layer 1006 may be an n-type layer, and second semiconductor layer 1010 may be a p-type layer. For example, first semiconductor layer 1006 may be an n-doped GaN layer (e.g., doped with Si or Ge), and second semiconductor layer 1010 may be a p-doped GaN layer (e.g., doped with Mg, Ca, Zn, or Be). Active layers 1008 may include, for example, one or more GaN layers, one or more InGaN layers, one or more AlInGaP layers, and the like, which may form one or more heterostructures, such as one or more quantum wells or MQWs.

In some embodiments, first wafer 1002 may also include a bonding layer. Bonding layer 1012 may include various materials, such as a metal, an oxide, a dielectric, CuSn, AuTi, or the like. In one example, bonding layer 1012 may include p-contacts and/or n-contacts (not shown). In some embodiments, other layers may also be included on first wafer 1002, such as a buffer layer between substrate 1004 and first semiconductor layer 1006. The buffer layer may include various materials, such as polycrystalline GaN or AlN. In some embodiments, a contact layer may be between second semiconductor layer 1010 and bonding layer 1012. The contact layer may include any suitable material for providing an electrical contact to second semiconductor layer 1010 and/or first semiconductor layer 1006.

First wafer 1002 may be bonded to wafer 1003 that includes drive circuits 1011 and bonding layer 1013 as described above, via bonding layer 1013 and/or bonding layer 1012. Bonding layer 1012 and bonding layer 1013 may be made of the same material or different materials. Bonding layer 1013 and bonding layer 1012 may be substantially flat. First wafer 1002 may be bonded to wafer 1003 by various methods, such as metal-to-metal bonding, eutectic bonding, metal oxide bonding, anodic bonding, thermo-compression bonding, ultraviolet (UV) bonding, and/or fusion bonding.

As shown in FIG. 10B, first wafer 1002 may be bonded to wafer 1003 with the p-side (e.g., second semiconductor layer 1010) of first wafer 1002 facing down (i.e., toward wafer 1003). After bonding, substrate 1004 may be removed from first wafer 1002, and first wafer 1002 may then be processed from the n-side. The processing may include, for example, the formation of certain mesa shapes for individual LEDs, as well as the formation of optical components corresponding to the individual LEDs.

As described above, it can be challenging to precisely align the bonding pads on the micro-LED arrays with the bonding pads on the drive circuits and form reliable bonding at the interfaces that may include both dielectric materials (e.g., SiO₂, SiN, or SiCN) and metal (e.g., Cu, Au, or Al) bonding pads. For example, when the pitch of the micro-LED device is about 2 to 4 microns or lower, the bonding pads may have a linear dimension less than about 1 μm in order to avoid shorting to adjacent micro-LEDs and to improve bonding strength of the dielectric bonding. The small bonding pads may be less tolerant to misalignments between the bonding pads, which may reduce the metal bonding area, increase the contact resistance (or may even result in an open circuit), and/or cause diffusion of metal atoms to the dielectric materials and the semiconductor materials. Thus, precise alignment of the bonding pads at the bonding surface of a micro-LED array and bonding pads at the bonding surface of a backplane wafer may be needed, which can be difficult to achieve using existing alignment and bonding techniques.

Lattice mismatch between the epitaxial layers and the growth substrate may cause strains in the epitaxial layers, which may cause bowing of the epitaxial layers and the growth substrate. For example, if GaN is used as the epitaxial material and sapphire is used as the growth substrate, the mismatch in the crystal lattices of GaN and sapphire may cause strain and bowing. As such, the micro-LED wafer may not be flat before the bonding, making it even more difficult to align and bond the micro-LED wafer to the CMOS backplane. For example, the bowing may change the lateral positions of alignment marks and may cause voids between the micro-LED wafer and the CMOS backplane, especially near the center of the wafer stack. These voids may cause defects in the LEDs. In some cases, an epitaxial layer grown with little or no strain (e.g., lattice matched to the growth substrate) at an elevated epitaxial growth temperature (e.g., greater than about 500° C.) may become strained at room temperature due to different coefficients of temperature expansion (CTEs) of the epitaxial layer and the substrate (e.g., GaAs substrate). In some cases, bonding a micro-LED wafer and a CMOS backplane at an elevated temperature may also cause bowing of the wafer stack due to different CTEs of the growth substrate (e.g., sapphire or GaAs substrate) of the micro-LED wafer and the substrate (e.g., silicon wafer) of the CMOS backplane. It can be challenging to match either the sapphire substrate or the GaAs substrates with state-of-the-art Si backplanes (e.g., on 12″ or 300-mm silicon wafer).

As such, there may be various reliability and yield issues caused by the CTE mismatch and crystal structure mismatch. For example, it can be challenging to reduce bowing and compensate for CTE mismatches between silicon and sapphire or GaAs. Therefore, it can be beneficial to grow epitaxial layers of micro-LEDs on Si substrates that have the same material and size as the silicon CMOS backplanes. GaN-based blue and green LEDs may be grown on silicon substrates, but GaN-based blue and green LEDs grown on silicon substrates may have a lower wall-plug efficiency than GaN-based blue and green LEDs grown on sapphire substrates, even though GaN epitaxial stacks grown on Si substrates can be very attractive for small micro-LEDs due to the relatively low difficulty in integration with CMOS backplanes.

GaN-based red light-emitting LEDs may generally have lower internal quantum efficiency than GaN-based blue and green LEDs. InGaAlP-based red light-emitting LEDs may have higher quantum efficiency, but gallium arsenide substrates for growing InGaAlP-based red light-emitting LEDs may be mostly available in wafers with diameters of about 4″ or 6″. This may limit the manufacture productivity and increase the cost. The material brittleness of GaAs wafers may also pose a risk for high-volume production. Furthermore, integrating red LEDs grown on GaAs substrates with silicon CMOS backplanes may also need thermal management improvement, for example, to reduce wafer bowing as described above. Thus, it may also be beneficial to grow red light-emitting epitaxial structures on silicon wafers. However, to achieve high-performance (e.g., high-efficiency) red micro-LEDs on silicon wafer, new heterostructure designs may be needed.

In some implementations, to overcome some of the above-described limitations (e.g., to reduce the number of de-bonding and bonding processes) and other limitations (e.g., internal electric field that may be caused by polarization-induced electric field and built-in depletion electric field and may contribute to Quantum-Confined Stark Effect (QCSE)), epitaxial structures of LEDs may be grown by growing n-type semiconductor layers after growing p-type semiconductor layers and the active layers (referred to as “n-side up”), rather than growing p-type semiconductor layers after growing the n-type semiconductor layers and the active layers (referred to as “p-side up”). However, to grow “n-side up” GaN epitaxial layers on sapphire or silicon substrates or grow “n-side up” InGaAlP epitaxial layers on GaAs or silicon substrates, the p-type contact layer may have greatly mismatched wide bandgaps, and thus may not be suitable for use as an intermediate layer between the growth substrate and the active region because it may cause the active region to become polycrystalline and decrease the recombination efficiency.

In addition, in red micro-LEDs made in InₓGa_{y}Al_{z}P_{0.5} epitaxial layers grown on GaAs substrates, the n-type semiconductor (e.g., InGaAlP or InAlP) layer, the InGaAlP/InGaP multiple quantum well layers, and the p-type semiconductor (e.g., InGaAlP or InAlP) layer may generally have in-plane compressive strain due to, for example, the difference between the lattice constant of the GaAs substrate and the lattice constant of the InₓGa_{y}Al_{z}P_{0.5} layers. Even though an InₓGa_{y}Al_{z}P_{0.5} epitaxial layers may be grown to have either compressive in-plane strain or tensile in-plane strain on a GaAs wafer, in some cases, an InₓGa_{y}Al_{z}P_{0.5} epitaxial layer grown with tensile strain or no strain (e.g., lattice matched to the GaAs substrate) may become compressive-strained at room temperature due to different coefficients of temperature expansion (CTEs) of the epitaxial layer and the GaAs substrate. Quantum well layers having in-plane compressive strain may increase the proportion of heavy holes and the effective mass of the holes, thereby reducing the mobility of the holes and the diffusion of the holes to the mesa sidewall regions that may cause non-radiative recombination at the mesa sidewall regions, and thus may improve the quantum efficiency of the micro-LEDs. However, the compressive strain in the epitaxial layers may cause a large bow of the wafer that includes the epitaxial layers grown thereon.

According to certain embodiments, a red micro-LED wafer may include GaP epitaxial structures grown on a silicon substrate, rather than a GaAs substrate. The GaP epitaxial structures may include in-plane lattice matched epitaxial layers because GaP materials may have lattice structures matching the lattice structure of silicon wafer. The GaP epitaxial structures may include indium-enriched InGaAsP quantum-well layers and an AlGaP etch stop layer. For example, the growth process may start with growing, on the silicon substrate, a GaAs buffer layer that closely matches the lattice structure of the silicon substrate. The subsequent layers may be grown using the same material (e.g., GaP) with the addition of Al and/or In for some layers. The active region may include quaternary materials (e.g., InGaAsP) that may emit red light. In some embodiments, the GaP epitaxial structures may be grown by growing the n-type epitaxial layers before growing the active layers and the p-type epitaxial layers in a “p-side up” epitaxial growing process. In some embodiments, the GaP epitaxial structures may be grown using modified doping strategies in “n-side up” epitaxial growing process.

In one example, a red light-emitting micro-LED wafer may include a silicon substrate, a p-GaP buffer layer grown on the silicon substrate, p-type GaP layers (e.g., a p-GaP contact layer and/or a p-AlGaP cladding layer) grown on the p-GaP buffer layer, InGaAsP/InGaP active layers grown on the p-type GaP layers, and n-type GaP layers (e.g., an n-AlGaP cladding layer and/or an n-GaP contact layer) grown on the active layers. The InGaAsP quantum-well layers may be direct-bandgap materials and may emit red light. The GaP base materials may have large bandgaps and thus may not absorb the emitted light (i.e., transparent to the emitted light).

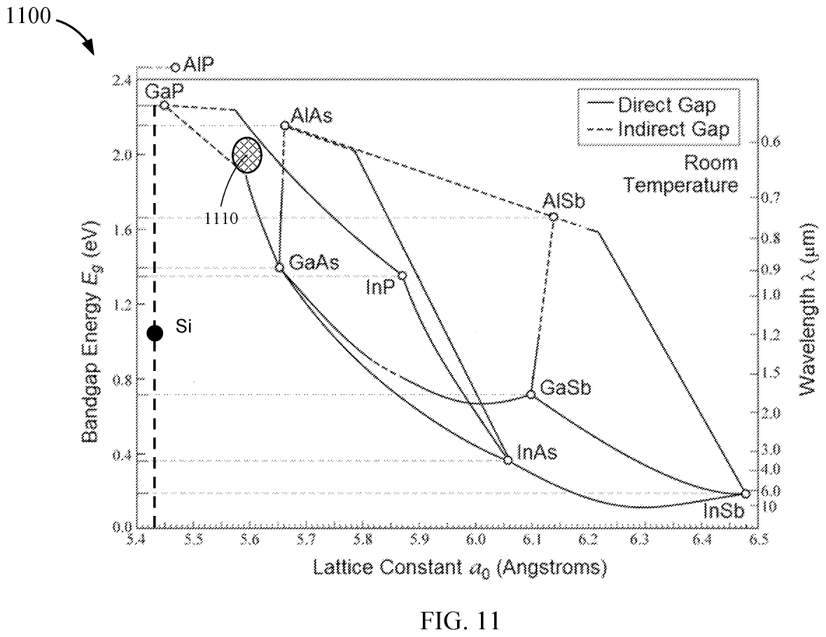

FIG. 11 includes a diagram 1100 illustrating bandgap energy levels, corresponding emission wavelengths, and lattice constants of semiconductor materials having different compositions. In FIG. 11, the horizontal axis corresponds to the lattice constants of different semiconductor materials, the primary vertical axis corresponds to the energy bandgaps of the semiconductor materials, and the secondary vertical axis shows the light emission wavelengths corresponding to the energy bandgaps. Materials delineated by solid lines correspond to direct gap semiconductor materials, while materials delineated by dashed lines correspond to indirect gap semiconductor materials.

FIG. 11 shows that GaP may have a lattice constant (e.g., about 5.45 Å) matching the lattice constant of Si (e.g., about 5.43 Å), and thus may be used as the buffer layer on Si substrate for growing epitaxial layers of GaP-based red light-emitting micro-LEDs. As illustrated, GaP may be an indirect bandgap material and may have an energy bandgap about 2.26 eV. InₓGa₁₋ₓAs_{y}P_{1-y} represented by a region 1110 in FIG. 11 may have a lattice constant about 5.58 Å (about 2.7% greater than that of the silicon substrate) and may be a direct bandgap material with an energy bandgap about 1.9 eV. Therefore, InₓGa₁₋ₓAs_{y}P_{1-y} may be used as the red light-emitting quantum well layers to emit light with wavelengths between about 600 nm and about 700 nm. InₓGa₁₋ₓP may have a lattice constant about 5.49 Å (about 1% greater than that of the silicon substrate) and may be an indirect bandgap material with an energy bandgap about 2.2 eV. Therefore, InₓGa₁₋ₓP may not absorb photons emitted in the InₓGa₁₋ₓAs_{y}P_{1-y} quantum well layers and can be used as the quantum barrier layers for confining carriers in the InₓGa₁₋ₓAs_{y}P_{1-y} quantum well layers.

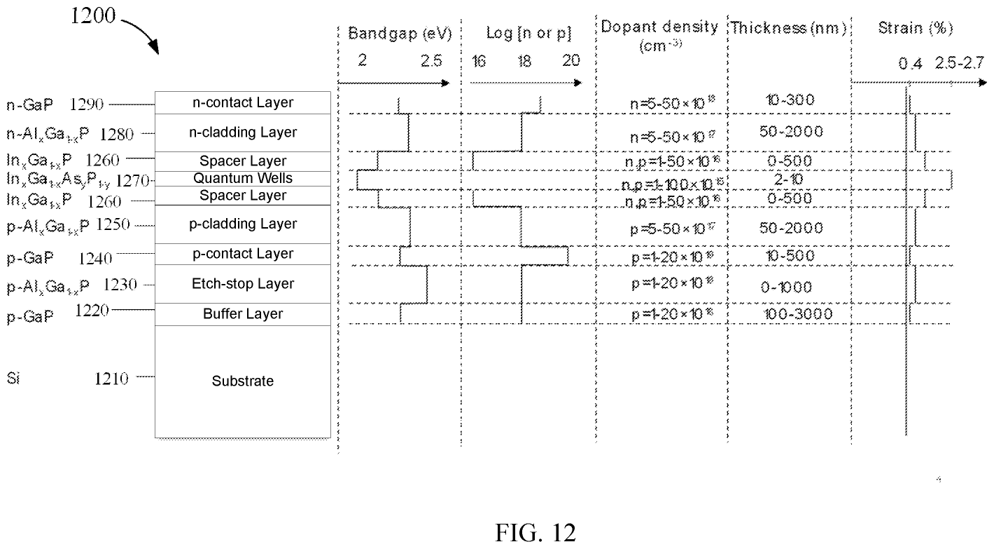

FIG. 12 illustrates an example of a micro-LED wafer 1200 including a red light-emitting epitaxial structure according to certain embodiments. In the illustrated example, micro-LED wafer 1200 may include a silicon substrate 1210, which may be a 6-inch wafer, an 8-inch wafer, a 12-inch wafer, and the like, and may have an offcut angle about 0-4 degrees. A buffer layer 1220 may be epitaxially grown on silicon substrate 1210. Buffer layer 1220 may include, for example, a p-doped GaP layer. The p-doped GaP buffer layer may have a thickness about 100-3000 nm, and may be doped with, for example, C, Mg, Zn, Be, or a combination thereof, at a dopant density about 1-20×10¹⁸ cm⁻³. As described above, GaP and Si may have similar lattice constants, and thus the p-doped GaP buffer layer may have a low strain and a low defect density. An optional etch-stop layer 1230 may be grown on buffer layer 1220. Etch-stop layer 1230 may include, for example, a p-AlₓGa₁₋ₓP layer with a thickness about 0-1000 nm and 0<x≤0.5. Etch-stop layer 1230 may be doped with, for example, C, Mg, Zn, Be, or a combination thereof, at a dopant density about 1-20×10¹⁸ cm⁻³.

A p-contact layer 1240 may be grown on etch-stop layer 1230. P-contact layer 1240 may include, for example, a p-GaP layer with a thickness about 10-500 nm, and may be doped at a dopant density about 1-20×10¹⁹ cm⁻³ with C, Mg, Zn, Be, or a combination thereof. A p-cladding layer 1250 may be grown on p-contact layer 1240. P-cladding layer 1250 may include, for example, a p-AlₓGa₁₋ₓP layer with a thickness about 50-2000 nm and 0<x≤0.5. P-cladding layer 1250 may be doped at a dopant density about 5-50×10¹⁷ cm⁻³ with C, Mg, Zn, Be, or a combination thereof.

A spacer layer 1260 (e.g., a quantum barrier layer) may be grown on p-cladding layer 1250. Spacer layer 1260 may include, for example, an InₓGa₁₋ₓP layer with a thickness about 0-500 nm and 0<x≤0.2. Spacer layer 1260 may be undoped, unintentionally doped, or lightly doped at a dopant density about 1-50×10¹⁶ cm⁻³ with C, Mg, Zn, Be, Si, Ge, S, Se, Te, or a combination thereof. A quantum well layer 1270 may be grown on spacer layer 1260. Quantum well layer 1270 may include, for example, an InₓGa₁₋ₓAs_{y}P_{1-y} layer with a thickness about 2-10 nm, 0<x≤0.55, and 0<y≤0.3. Quantum well layer 1270 may be undoped, unintentionally doped, or lightly doped at a dopant density about 1-50×10¹⁶ cm⁻³ (e.g., about 1-100×10¹⁵ cm⁻³) with C, Mg, Zn, Be, Si, Ge, S, Se, Te, or a combination thereof. Spacer layer 1260 and quantum well layer 1270 may be alternately grown for multiple times (e.g., up to about 10 or more times) to form multiple quantum wells. Another spacer layer 1260 may be grown on the last quantum well layer 1270. Spacer layers 1260 and one or more quantum well layers 1270 may form the active region that may include a multi-quantum well (MQW).

An n-cladding layer 1280 may be grown on the active region. N-cladding layer 1280 may include, for example, an n-AlₓGa₁₋ₓP layer with a thickness about 50-2000 nm and 0<x≤0.5. N-cladding layer 1280 may be doped at a dopant density about 5-50×10¹⁷ cm⁻³ with Si, S, Ge, Te, Se, or a combination thereof. An n-contact layer 1290 may be grown on n-cladding layer 1280. N-contact layer 1290 may include, for example, an n-GaP layer with a thickness about 10-300 nm, and may be doped at a dopant density about 5-50×10¹⁸ cm⁻³ with Si, S, Ge, Te, Se, or a combination thereof.

FIG. 12 also shows the strain of each epitaxial layer caused by, for example, different lattice constants of the different epitaxial layers. As described above, the InₓGa₁₋ₓAs_{y}P_{1-y} quantum well layers may have a larger lattice constant than the InₓGa₁₋ₓP quantum barrier (spacer) layers, and thus may experience a compressive strain. FIG. 12 shows that the GaP-based layers (e.g., GaP contact layer, AlGaP cladding layer, and InGaP quantum barrier layers) sequentially grown before the InGaAsP quantum-well layers may generally have gradually increasing lattice constants, and thus the GaP-based layers grown before the InGaAsP quantum-well layers may have compressive strain. FIG. 12 also shows that the GaP-based layers (e.g., InGaP quantum barrier layers, AlGaP cladding layer, and GaP contact layer) sequentially grown after the InGaAsP quantum-well layers may generally have gradually decreasing lattice constants, and thus may experience tensile strain. The tensile strain of some epitaxial layers may counter the compressive strain of other epitaxial layers, thereby reducing the net strain and the bow of the micro-LED wafer including the epitaxial layers. Due to the low bow of the micro-LED wafer, the bonding of the micro-LED wafer to a backplane may be easier, stronger, more accurate, and more reliable.

In addition, the strained epitaxial layers for strain balancing and bow reduction may result in an improvement in the efficiency of micro-LEDs at high operating current densities and elevated temperatures. For example, the tensile-strained semiconductor layers on the active region may lead to higher potential barrier. The increase in the potential barrier height may result in a lower leakage current and a higher wall plug efficiency at elevated temperatures and/or high operating current densities.

As described above, integrating LEDs grown on a silicon substrate with a CMOS backplane formed in a silicon substrate may be easier and may achieve reduced wafer bowing due to CTE matching between the two substrates. In addition, silicon substrates with diameters of 8 to 12 inches are readily available, while GaAs substrates may be limited to 4-6 inches in diameter (even though 8-inch GaAs substrates are being considered). Cost of Si substrates is also several times lower than that of GaAs substrates. Furthermore, growing heterostructures using the n-side-up growth process may decrease the number of subsequent processing steps (e.g., bonding to temporary wafer and de-bonding the temporary wafer) for fabrication of the micro-LEDs and bonding with the CMOS backplane. The processes disclosed herein may also allow unified fabrication processes with III-N-on-Si, where GaN-based blue and green light-emitting LEDs and GaP-based red light emitting LEDs may be grown on a same Si substrate to integrated micro-LEDs of different colors into a same wafer or a same die. The material system disclosed herein may also have significantly higher thermal conductivity, thereby providing a more stable thermal performance compared to other AlGaInP alloy material systems. Therefore, growing red light-emitting GaP-based LEDs on silicon wafers may improve the wafer integration, may be cost effective, may be more reliable, and may have higher efficiency, compared with red light-emitting LEDs grown on GaAs wafers.

Even though FIG. 12 shows that p-type GaP-based epitaxial layers may be grown before the growth of the active layers and n-type GaP-based epitaxial layers, in some other embodiments, n-type GaP-based epitaxial layers may be grown before the growth of the active layers and p-type GaP-based epitaxial layers.

In some embodiments, the epitaxial structure of micro-LED wafer 1200 may be etched, for example, from the side of n-contact layer 1290 to p-contact layer 1240, to form individual mesa structures for individual micro-LEDs, before bonding micro-LED wafer 1200 to a CMOS backplane. In some embodiments, a metal layer may be formed on n-contact layer 1290, and the micro-LED wafer may be bonded to a CMOS backplane, before the epitaxial structure is etched to form individual micro-LEDs.

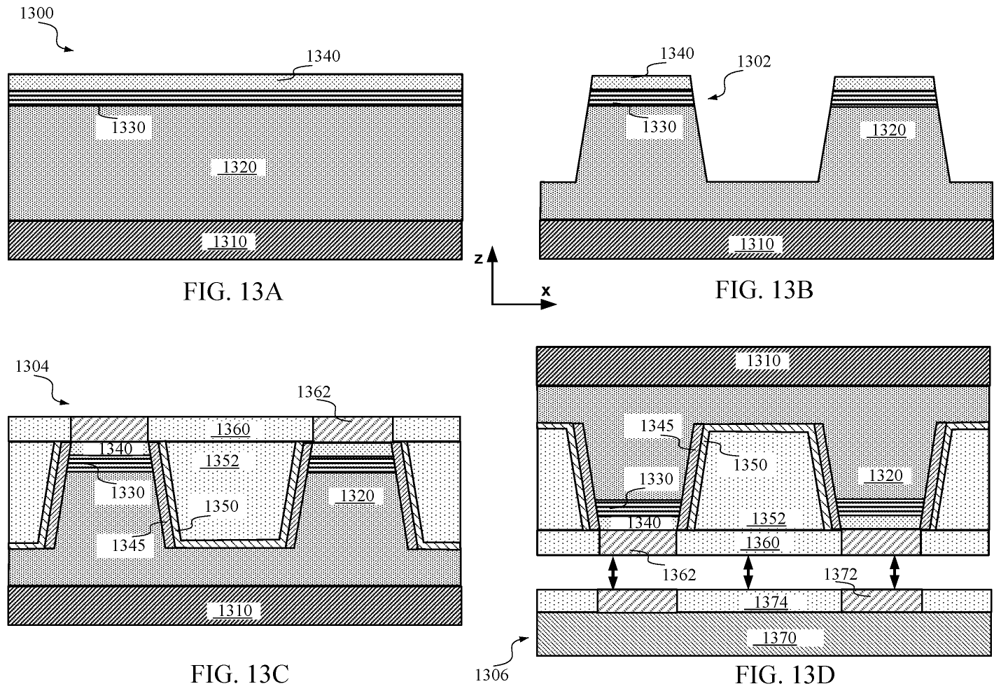

FIGS. 13A-13D illustrate an example of a process of fabricating a micro-LED device according to certain embodiments. FIG. 13A shows a micro-LED wafer 1300 including epitaxial layers grown on a substrate 1310. Micro-LED wafer 1300 may be an example of micro-LED wafer 1200, where substrate 1310 may be a silicon wafer and the epitaxial layers may be GaP-based semiconductor layers. For example, as described above with respect to FIG. 12, a GaP buffer layer (e.g., buffer layer 1220) may be formed on substrate 1310 to improve the lattice matching between substrate 1310 and the epitaxial layers, thereby reducing stress and defects in the epitaxial layers. The GaP buffer layer may be p-doped or n-doped. In some embodiments, an etch-stop layer (e.g., etch-stop layer 1230) may be formed on the GaP buffer layer. The epitaxial layers may also include first doped semiconductor layers 1320 (e.g., including p-GaP based p-contact layer 1240 and p-AlₓGa₁₋ₓP based p-cladding layer 1250), active layers 1330, and second doped semiconductor layers 1340 (e.g., including n-AlₓGa₁₋ₓP based n-cladding layer 1280 and n-GaP based n-contact layer 1290). Active layers 1330 may include multiple quantum wells or an MQW formed by thin quantum well layers (e.g., InₓGa₁₋ₓAs_{y}P_{1-y} quantum well layers 1270) sandwiched by barrier layers (e.g., InₓGa₁₋ₓP spacer layers 1260) as described above. The epitaxial layers may be grown layer-by-layer on substrate 1310 or the buffer layer as described above with respect to FIG. 12, using techniques such as VPE, LPE, MBE, or MOCVD.

FIG. 13B shows that micro-LED wafer 1300 may be etched from the side of second doped semiconductor layers 1340 to form semiconductor mesa structures 1302 for individual micro-LEDs. As shown in FIG. 13B, the etching may include etching through second doped semiconductor layers 1340, active layers 1330, and at least a portion of first doped semiconductor layers 1320. Thus, each semiconductor mesa structure 1302 formed by the etching may include second doped semiconductor layers 1340, active layers 1330, and a portion of first doped semiconductor layers 1320. For example, in some embodiments, p-contact layer 1240 may not be etched through and may be used as a common anode. In some embodiments, the etch may stop at the etch-stop layer. To perform the etching, an etch mask layer may be formed on second doped semiconductor layers 1340, and dry or wet etching may be performed from the side of second doped semiconductor layers 1340. Due to the etching from second doped semiconductor layers 1340, semiconductor mesa structure 1302 may have sidewalls that are inwardly tilted in the z direction. For example, the angle between the sidewalls and the surface-normal direction (the z direction) of micro-LED wafer 1300 may be between about 0° to about 30°, such as about 15°. In some embodiments, semiconductor mesa structures 1302 may have a conical shape, a parabolic shape, a truncated pyramid shape, or another shape. In some embodiments, after the etching, sidewalls of the etched semiconductor mesa structures 1302 may be treated, for example, using KOH or an acid, to remove regions that may be damaged by high-energy ions during the dry etching.

FIG. 13C shows that micro-LED wafer 1300 may be further processed from the side of second doped semiconductor layers 1340 to form a wafer 1304 that includes an array of micro-LEDs. In the illustrated example, a passivation layer 1345 may be formed on sidewalls of semiconductor mesa structures 1302. Passivation layer 1345 may include, for example, SiO₂, SiN, Al₂O₃, or a semiconductor material. Passivation layer 1345 may electrically isolate semiconductor mesa structures 1302. A reflective metal layer 1350 (e.g., including Al, Au, Ag, Cu, Ti, Ni, Pt, or a combination thereof) may be formed on passivation layer 1345 to optically isolate individual micro-LEDs and improve the light extraction efficiency. In some embodiments, reflective metal layer 1350 may fill regions between semiconductor mesa structures 1302. In some embodiments, a dielectric material 1352 (e.g., SiO₂) may be deposited on reflective metal layer 1350 and in regions between semiconductor mesa structures 1302. Passivation layer 1345, reflective metal layer 1350, and dielectric material 1352 may be formed using suitable deposition techniques, such as chemical vapor deposition (CVD), physical vapor deposition (PVD), plasma-enhanced chemical vapor deposition (PECVD), atomic-layer deposition (ALD), laser metal deposition (LMD), or sputtering. A back reflector and contact 1362 may be form in a dielectric material 1360 and may contact second doped semiconductor layers 1340 of a corresponding semiconductor mesa structure 1302. Back reflector and contact 1362 may include, for example, Au, Ag, Al, Ti, Cu, Ni, ITO, or a combination thereof. Even though not shown in FIG. 13C, in some embodiments, one or more metal interconnect layers may be formed on back reflector and contact 1362. The one or more metal interconnect layers may include a bonding layer that includes metal bonding pads in a dielectric layer as described above with respect to, for example, FIG. 8B.

FIG. 13D shows that wafer 1304 may be bonded to a backplane wafer 1306 in a hybrid bonding process. Backplane wafer 1306 may include a substrate 1370 with electrical circuits formed thereon. The electrical circuits may include digital and analog pixel drive circuits for driving individual micro-LEDs. A plurality of metal pads 1372 (e.g., copper or tungsten pads) may be formed in a dielectric layer 1374 (e.g., including SiO₂ or SiN). In some embodiments, each metal pad 1372 may be an electrode (e.g., anode or cathode) for a micro-LED. Even though FIG. 13D only shows metal pads 1372 formed in one metal layer in one dielectric layer 1374, backplane wafer 1306 may include two or more metal layers formed in dielectric materials and interconnected by, for example, metal vias, as in many CMOS integrated circuits.

As described above with respect to, for example, FIGS. 8A-8D, in the hybrid bonding, the bonding surfaces of wafer 1304 and backplane wafer 1306 may be planarized, cleaned, and activated before the bonding. Wafer 1304 (or backplane wafer 1306) may be turned upside down and brought into contact with backplane wafer 1306 (or wafer 1304) such that dielectric layer 1374 and dielectric material 1360 may be in direct contact and may be bonded together with or without heat treatment due to the surface activation. In some embodiments, a compression pressure may be applied to wafer 1304 and backplane wafer 1306 such that the bonding layers are pressed against each other. After the bonding of the dielectric materials, an annealing process may be performed at an elevated temperature to bond the metal pads (e.g., back reflector and p-contacts 1362 and metal pads 1372) at the bonding surfaces.

After the bonding of wafer 1304 and backplane wafer 1306, substrate 1310, the buffer layer, and/or the etch-stop layer of wafer 1304 may be removed. In some embodiments, the etch-stop layer may not be removed and may be used as a common anode or a common cathode. In some embodiments, a transparent conductive oxide (TCO) layer (e.g., such as an ITO layer) may optionally be formed on the exposed first doped semiconductor layers 1320. The TCO layer may form a common cathode or anode for the micro-LEDs. In the illustrated example, non-native lenses may be fabricated in a dielectric material (e.g., SiN or SiO₂) or an organic material, and may be bonded to the TCO layer. In some embodiments, non-native lenses may be fabricated in a dielectric material deposited on the TCO layer or another common anode or cathode layer. In some embodiments, native lenses may be fabricated in first doped semiconductor layers 1320. The bonded wafer stack may then be diced to form individual micro-LED devices each including a micro-LED array and the corresponding driving circuits.

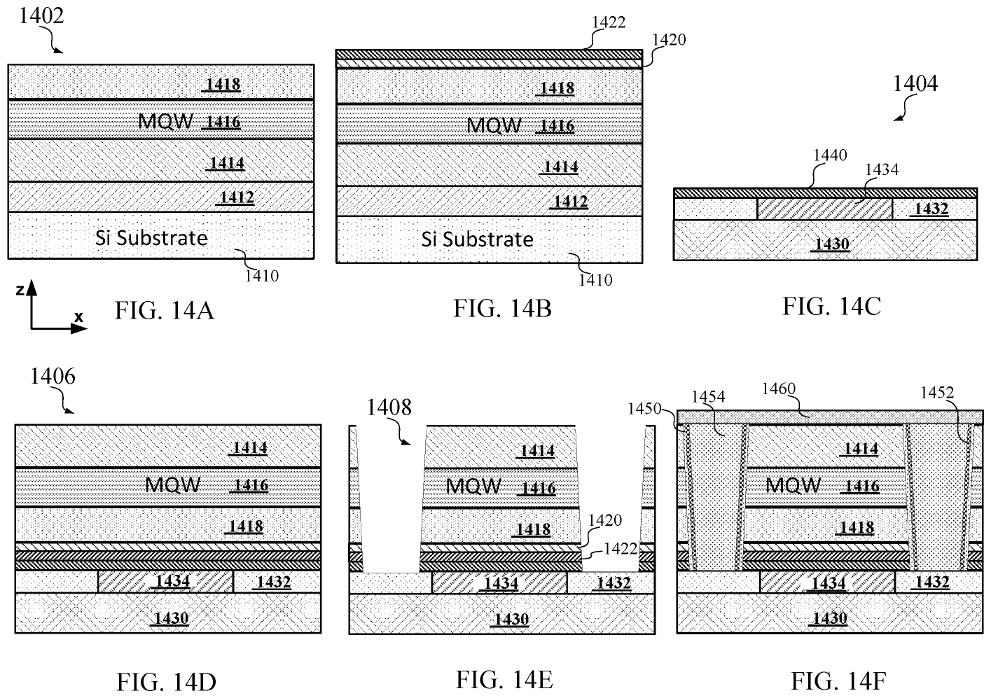

FIGS. 14A-14F illustrate an example of a method of fabricating a micro-LED device using alignment-free metal-to-metal bonding and post-bonding mesa formation processes according to certain embodiments. FIG. 14A shows a micro-LED wafer 1400 including epitaxial layers grown on a substrate 1410. Micro-LED wafer 1400 may be an example of micro-LED wafer 1200, where substrate 1410 may be a silicon wafer and the epitaxial layers may include GaP-based semiconductor layers. As described above with respect to FIG. 12, a buffer layer 1412 (e.g., buffer layer 1220) may be formed on substrate 1410 to improve the lattice matching between substrate 1410 and the epitaxial layers, thereby reducing stress and defects in the epitaxial layers. Buffer layer 1412 may be p-doped or n-doped. In some embodiments, an etch-stop layer (e.g., etch-stop layer 1230) may be formed on buffer layer 1412. The epitaxial layers may also include first doped semiconductor layers 1414 (e.g., including p-GaP based p-contact layer 1240 and p-AlₓGa₁₋ₓP based p-cladding layer 1250), active layers 1416, and second doped semiconductor layers 1418 (e.g., including n-AlₓGa₁₋ₓP based n-cladding layer 1280 and n-GaP based n-contact layer 1290). Active layers 1416 may include multiple quantum wells or an MQW formed by thin quantum well layers (e.g., InₓGa₁₋ₓAs_{y}P_{1-y} quantum well layers 1270) sandwiched by barrier layers (e.g., InₓGa₁₋ₓP spacer layers 1260) as described above. The epitaxial layers may be grown layer-by-layer on substrate 1410 or buffer layer 1412 as described above with respect to FIG. 12, using techniques such as VPE, LPE, MBE, or MOCVD.

FIG. 14B shows a reflector layer 1420 and a bonding layer 1422 formed on second doped semiconductor layers 1418. Reflector layer 1420 may include, for example, a metal layer such as an aluminum layer, a silver layer, or a metal alloy layer. In some embodiments, reflector layer 1420 may include a distributed Bragg reflector formed by conductive materials (e.g., semiconductor materials or conductive oxides) or including conductive vias. In some embodiments, reflector layer 1420 may include one or more sublayers. Reflector layer 1420 may be formed on second doped semiconductor layers 1418 in a deposition process. Bonding layer 1422 may include a metal layer, such as a titanium layer, a copper layer, an aluminum layer, a gold layer, or a metal alloy layer. In some embodiments, bonding layer 1422 may include a eutectic alloy, such as Au—In, Au—Sn, Au—Ge, or Ag—In. Bonding layer 1422 may be formed on reflector layer 1420 by a deposition process and may include one or more sublayers.

FIG. 14C shows a backplane wafer 1404 that includes a substrate 1430 with electrical circuits formed thereon. The electrical circuits may include digital and analog pixel drive circuits for driving individual micro-LEDs. A plurality of metal pads 1434 (e.g., copper or tungsten pads) may be formed in a dielectric layer 1432 (e.g., including SiO₂ or SiN). In some embodiments, each metal pad 1434 may be an electrode (e.g., anode or cathode) for a micro-LED. In some embodiments, pixel drive circuits for each micro-LED may be formed in an area matching the size of a micro-LED (e.g., about 2 μm×2 μm), where the pixel drive circuits and the micro-LED may collectively form a pixel of a micro-LED display panel. Even though FIG. 14C only shows metal pads 1434 formed in one metal layer in one dielectric layer 1432, backplane wafer 1404 may include two or more metal layers formed in dielectric materials and interconnected by, for example, metal vias, as in many CMOS integrated circuits. In some embodiments, a planarization process, such as a chemical mechanical polishing (CMP) process, may be performed to planarize the exposed surfaces of metal pads 1434 and dielectric layer 1432. A bonding layer 1440 may be formed on dielectric layer 1432 and may be in physical and electrical contact with metal pads 1434. As bonding layer 1422, bonding layer 1440 may include a metal layer, such as a titanium layer, a copper layer, an aluminum layer, a gold layer, a metal alloy layer, or a combination thereof. In some embodiments, bonding layer 1440 may include a eutectic alloy. In some embodiments, only one of bonding layer 1440 or bonding layer 1422 may be used.

FIG. 14D shows that micro-LED wafer 1402 and backplane wafer 1404 may be bonded together to form a wafer stack 1406. Micro-LED wafer 1402 and backplane wafer 1404 may be bonded by the metal-to-metal bonding of bonding layer 1422 and bonding layer 1440. The metal-to-metal bonding may be based on chemical bonds between the metal atoms at the surfaces of the metal bonding layers. The metal-to-metal bonding may include, for example, thermo-compression bonding, eutectic bonding, or transient liquid phase (TLP) bonding. The metal-to-metal bonding process may include, for example, surface planarization, wafer cleaning (e.g., using plasma or solvents) at room temperatures, and compression and annealing at elevated temperatures, such as about 250° C. or higher, to cause diffusion of atoms. In eutectic bonding, a eutectic alloy including two or more metals and with a eutectic point lower than the melting point of the two or more metals may be used for low-temperature wafer bonding. Because the eutectic alloy may become a liquid at the elevated temperature, eutectic bonding may be less sensitive to surface flatness irregularities, scratches, particles contamination, and the like. After the bonding, buffer layer 1412 and substrate 1410 may be thinned or removed by, for example, etching, back grinding, or laser lifting, to expose first doped semiconductor layers 1414.

FIG. 14E shows that wafer stack 1406 may be etched from the side of the exposed first doped semiconductor layers 1414 to form mesa structures 1408 for individual micro-LEDs. As shown in FIG. 14E, the etching may include etching through first doped semiconductor layers 1414, active layers 1416, second doped semiconductor layers 1418, reflector layer 1420, and bonding layers 1422 and 1440, in order to singulate and electrically isolate mesa structures 1408. Thus, each singulated mesa structure 1408 may include first doped semiconductor layers 1414, active layers 1416, second doped semiconductor layers 1418, reflector layer 1420, and bonding layers 1422 and 1440. To perform the etching, an etch mask layer may be formed on first doped semiconductor layer 1414. The etch mask layer may be patterned by aligning a photomask with the backplane wafer (e.g., using alignment marks on backplane wafer 1404) such that the patterned etch mask formed in the etch mask layer may align with metal pads 1434. Therefore, regions of the epitaxial layers and bonding layers above metal pads 1434 may not be etched. Dielectric layer 1432 may be used as the etch-stop layer for the etching. Even though FIG. 14E shows that mesa structures 1408 have substantially vertical sidewalls, mesa structures 1408 may have other shapes as described above, such as a conical shape, a parabolic shape, or a truncated pyramid shape.

FIG. 14F shows that a passivation layer 1450 may be formed on sidewalls of mesa structures 1408, and a sidewall reflector layer 1452 may be formed on passivation layer 1450. Passivation layer 1450 may include a dielectric layer (e.g., SiO₂, SiN, or Al₂O₃) or an undoped semiconductor layer. Sidewall reflector layer 1452 may include, for example, a metal (e.g., Al) or a metal alloy. In some embodiments, gaps between mesa structures 1408 may be filled with a dielectric material 1454 and/or a metal. Passivation layer 1450, sidewall reflector layer 1452, and/or dielectric material 1454 may be formed using suitable deposition techniques, such as CVD, PVD, PECVD, ALD, LMD, or sputtering. In some embodiments, sidewall reflector layer 1452 may fill the gaps between mesa structures 1408. In some embodiments, a planarization process may be performed after the deposition of passivation layer 1450, sidewall reflector layer 1452, and/or dielectric material 1454. A common electrode layer 1460, such as a transparent conductive oxide (TCO) layer (e.g., an ITO layer) or a thin metal layer that may be transparent to light emitted in active layers 1416, may be formed on the first doped semiconductor layers 1414 to form n-contacts and a common-cathode for the micro-LEDs. Even though not shown in FIG. 14F, an array of micro-lenses may be formed on common electrode layer 1460 to extract and collimate light emitted in active layers 1416.

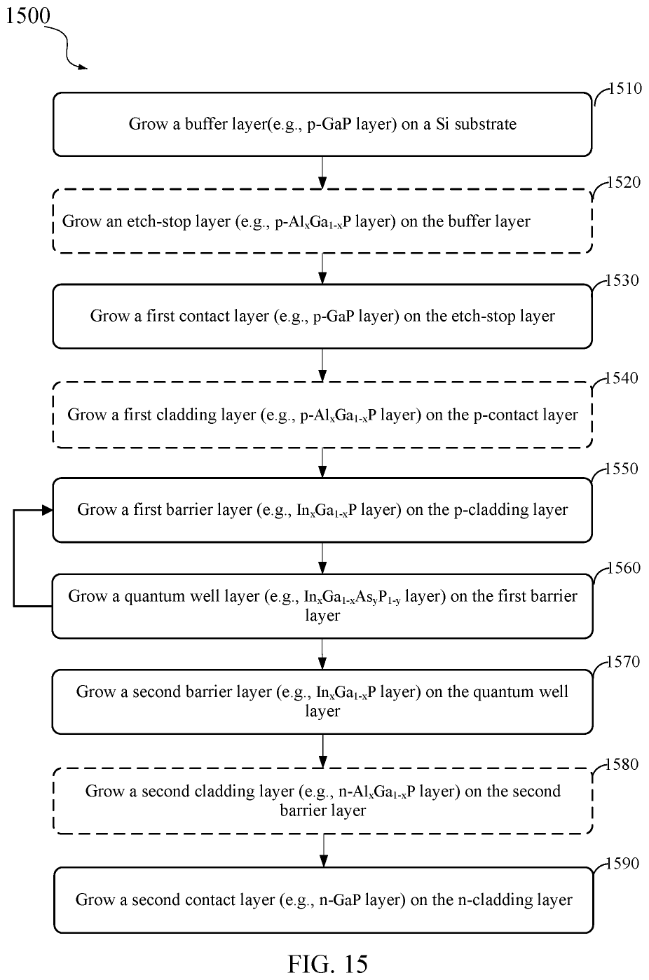

FIG. 15 includes a flowchart 1500 illustrating an example of a method of fabricating a micro-LED wafer (e.g., micro-LED wafer 1200) according to certain embodiments. It is noted that the operations illustrated in FIG. 15 provide particular processes for fabricating a micro-LED wafer. Other sequences of operations can also be performed according to alternative embodiments. For example, alternative embodiments may perform the operation in a different order. Moreover, the individual operations illustrated in FIG. 15 can include multiple sub-operations that can be performed in various sequences as appropriate for the individual operation. Furthermore, some operations can be added or removed depending on the particular applications. In some implementations, two or more operations may be performed in parallel. One of ordinary skill in the art would recognize many variations, modifications, and alternatives.

Operations in block 1510 of flowchart 1500 may include growing a buffer layer (e.g., p-GaP layer) on a Si substrate. The silicon substrate may have a diameter greater than 6 inches, such as 8-12 inches. In some embodiments, the buffer layer (e.g., p-GaP layer) may be characterized by a thickness between about 100 and about 3000 nm, and a dopant density between about 1×10¹⁸ and about 20×10¹⁸ cm⁻³, where the p-GaP buffer layer may be doped with C, Mg, Zn, Be, or a combination thereof.

Optional operations in block 1520 may include growing an etch-stop layer (e.g., p-AlₓGa₁₋ₓP layer) on the buffer layer. In some embodiments, the etch-stop layer may be characterized by a composition of AlₓGa₁₋ₓP with 0<x≤0.5, a thickness between 0 and about 1000 nm, and undoped or doped with C, Mg, Zn, Be, or a combination thereof at a dopant density between about 1×10¹⁸ and about 20×10¹⁸ cm⁻³.

Operations in block 1530 may include growing a first contact layer (e.g., p-GaP layer) on the etch-stop layer or the buffer layer. In some embodiments, the first contact layer may be characterized by a thickness between about 10 and about 500 nm, and a dopant density between about 1×10¹⁹ and about 20×10¹⁹ cm⁻³, where the first contact layer may be doped with C, Mg, Zn, Be, or a combination thereof.

Optional operations in block 1540 may include growing a first cladding layer (e.g., p-AlₓGa₁₋ₓP layer) on the first contact layer. In some embodiments, the first cladding layer may be characterized by a composition of AlₓGa₁₋ₓP with 0<x≤0.5, a thickness between 0 about 50 and about 2000 nm, and undoped or doped with C, Mg, Zn, Be, or a combination thereof at a dopant density between about 5×10¹⁷ and about 50×10¹⁷ cm⁻³.

Operations in block 1550 may include growing a first barrier layer (e.g., InₓGa₁₋ₓP spacer layer) on the first cladding layer. In some embodiments, the first barrier layer may be characterized by a composition of InₓGa₁₋ₓP with 0<x≤0.2, a thickness between 0 and about 500 nm, and undoped, unintentionally doped, or lightly doped with C, Mg, Zn, Be, Si, Ge, S, Se, Te, or a combination thereof at a dopant density between about 1×10¹⁶ and about 50×10¹⁶ cm⁻³.

Operations in block 1560 may include growing a quantum well layer (e.g., InₓGa₁₋ₓAs_{y}P_{1-y} layer) on the first barrier layer. In some embodiments, the quantum well layers may be characterized by a composition of InₓGa₁₋ₓAs_{y}P_{1-y} with 0<x≤0.55 and 0<y≤0.3, a thickness between about 2 and about 10 nm, and undoped, unintentionally doped, or doped with C, Mg, Zn, Be, Si, Ge, S, Se, Te, or a combination thereof at a dopant density less than about 50×10¹⁶ cm⁻³, such as between about 1×10¹⁵ and about 100×10¹⁵ cm⁻³. In some embodiments, operations at block 1550 and block 1560 may be performed for multiple (e.g., up to 10 or more) times to form multiple quantum wells.

Operations in block 1570 may include growing a second barrier layer (e.g., InₓGa₁₋ₓP spacer layer) on the quantum well layer. The second barrier layer may be similar to the first barrier layer. For example, in some embodiments, the second barrier layer may be characterized by a composition of InₓGa₁₋ₓP with 0<x≤0.2, a thickness between 0 and about 500 nm, and undoped, unintentionally doped, or doped with C, Mg, Zn, Be, Si, Ge, S, Se, Te, or a combination thereof at a dopant density between about 1×10¹⁶ and about 50×10¹⁶ cm⁻³.

Optional operations in block 1580 may include growing a second cladding layer (e.g., n-AlₓGa₁₋ₓP layer) on the second barrier layer. In some embodiments, the second cladding layer may be characterized by a composition of AlₓGa₁₋ₓP with 0<x≤0.5, a thickness between about 50 and about 2000 nm, and undoped or doped with Si, S, Ge, Te, Se, or a combination thereof at a dopant density between about 5×10¹⁷ and about 50×10¹⁷ cm⁻³.

Operations in block 1590 may include growing a second contact layer (e.g., n-GaP layer) on the second cladding layer. In some embodiments, the second contact layer may be characterized by a thickness between about 10 and about 300 nm, and a dopant density between about 5×10¹⁸ and about 50×10¹⁸ cm⁻³, where the second GaP contact layer may be doped with Si, S, Ge, Te, Se, or a combination thereof.

In some other embodiments, n-type GaP-based epitaxial layers may be grown on the silicon substrate before the growth of the active layers and p-type GaP-based epitaxial layers. For example, an n-GaP buffer layer may be grown on the silicon substrate, an n-AlGaP etch-stop layer may be grown on the n-GaP buffer layer, an n-GaP contact layer may be grown on the n-AlGaP etch-stop layer, and an n-AlGaP cladding layer may be grown on the n-GaP contact layer. Active layers including quantum barrier layers and quantum well layers may be grown on the n-AlGaP cladding layer. A p-AlGaP cladding layer and a p-GaP contact layer may then be grown on the active layers.

In some embodiments, the micro-LED wafer may be etched, for example, from the side of the n-contact layer to the p-contact layer, to form individual mesa structures for individual micro-LEDs as described above with respect, for example, FIG. 13B. The etch-stop layer may be used as the etch-stop layer for the etching. As described above with respect, for example, FIG. 13C, a passivation layer and a sidewall reflector layer may be formed on side walls of each mesa structure. In some embodiments, n-electrodes and/or n-side reflectors may be formed on the n-contact layer. A bonding layer may be formed on the n-electrodes and/or n-side reflectors. The bonding layer may be used to bond the micro-LED wafer to a CMOS backplane as described above with respect, for example, FIG. 13D. After the bonding, the substrate, the buffer layer, and/or the etch-stop layer may be removed from the backside to expose the p-contact layer, and p-electrodes may be formed on the p-contact layer. In some embodiments, the etch-stop layer may not be removed and may be used as a common anode. In some embodiments, the p-contact layer may not be etched and may be used as a common anode. In some embodiments, a transparent conductive oxide layer may be deposited on the p-contact layer to form a common anode layer. In this way, no temporary substrate may be used in the micro-LED fabrication and bonding process.

In some embodiments, the etch-stop layer may not be needed. A bonding layer may be formed on the n-contact layer, and the micro-LED wafer may be bonded to a CMOS backplane using the bonding layer. After the bonding, the substrate and/or the buffer layer may be removed, and the epitaxial layers may then be processed from the side of the p-contact layer to form individual mesa structures for individual micro-LEDs, as described above with respect to FIGS. 14A-14F.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

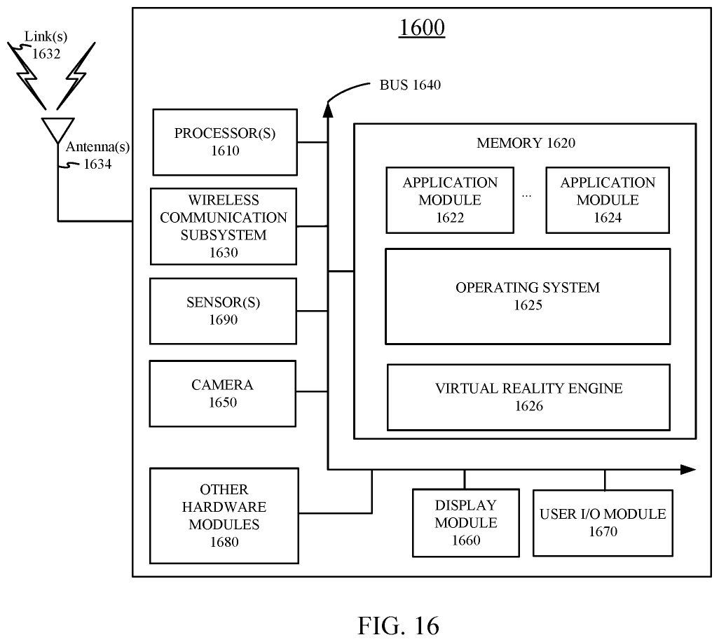

FIG. 16 is a simplified block diagram of an example electronic system 1600 of an example near-eye display (e.g., HMD device) for implementing some of the examples disclosed herein. Electronic system 1600 may be used as the electronic system of an HMD device or other near-eye displays described above. In this example, electronic system 1600 may include one or more processor(s) 1610 and a memory 1620. Processor(s) 1610 may be configured to execute instructions for performing operations at a number of components, and can be, for example, a general-purpose processor or microprocessor suitable for implementation within a portable electronic device. Processor(s) 1610 may be communicatively coupled with a plurality of components within electronic system 1600. To realize this communicative coupling, processor(s) 1610 may communicate with the other illustrated components across a bus 1640. Bus 1640 may be any subsystem adapted to transfer data within electronic system 1600. Bus 1640 may include a plurality of computer buses and additional circuitry to transfer data.

Memory 1620 may be coupled to processor(s) 1610. In some embodiments, memory 1620 may offer both short-term and long-term storage and may be divided into several units. Memory 1620 may be volatile, such as static random access memory (SRAM) and/or dynamic random access memory (DRAM) and/or non-volatile, such as read-only memory (ROM), flash memory, and the like. Furthermore, memory 1620 may include removable storage devices, such as secure digital (SD) cards. Memory 1620 may provide storage of computer-readable instructions, data structures, program modules, and other data for electronic system 1600. In some embodiments, memory 1620 may be distributed into different hardware modules. A set of instructions and/or code might be stored on memory 1620. The instructions might take the form of executable code that may be executable by electronic system 1600, and/or might take the form of source and/or installable code, which, upon compilation and/or installation on electronic system 1600 (e.g., using any of a variety of generally available compilers, installation programs, compression/decompression utilities, etc.), may take the form of executable code.

In some embodiments, memory 1620 may store a plurality of application modules 1622 through 1624, which may include any number of applications. Examples of applications may include gaming applications, conferencing applications, video playback applications, or other suitable applications. The applications may include a depth sensing function or eye tracking function. Application modules 1622-1624 may include particular instructions to be executed by processor(s) 1610. In some embodiments, certain applications or parts of application modules 1622-1624 may be executable by other hardware modules 1680. In certain embodiments, memory 1620 may additionally include secure memory, which may include additional security controls to prevent copying or other unauthorized access to secure information.

In some embodiments, memory 1620 may include an operating system 1625 loaded therein. Operating system 1625 may be operable to initiate the execution of the instructions provided by application modules 1622-1624 and/or manage other hardware modules 1680 as well as interfaces with a wireless communication subsystem 1630 which may include one or more wireless transceivers. Operating system 1625 may be adapted to perform other operations across the components of electronic system 1600 including threading, resource management, data storage control and other similar functionality.

Wireless communication subsystem 1630 may include, for example, an infrared communication device, a wireless communication device and/or chipset (such as a Bluetooth® device, an IEEE 802.11 device, a Wi-Fi device, a WiMax device, cellular communication facilities, etc.), and/or similar communication interfaces. Electronic system 1600 may include one or more antennas 1634 for wireless communication as part of wireless communication subsystem 1630 or as a separate component coupled to any portion of the system. Depending on desired functionality, wireless communication subsystem 1630 may include separate transceivers to communicate with base transceiver stations and other wireless devices and access points, which may include communicating with different data networks and/or network types, such as wireless wide-area networks (WWANs), wireless local area networks (WLANs), or wireless personal area networks (WPANs). A WWAN may be, for example, a WiMax (IEEE 802.16) network. A WLAN may be, for example, an IEEE 802.11x network. A WPAN may be, for example, a Bluetooth network, an IEEE 802.15x, or some other types of network. The techniques described herein may also be used for any combination of WWAN, WLAN, and/or WPAN. Wireless communications subsystem 1630 may permit data to be exchanged with a network, other computer systems, and/or any other devices described herein. Wireless communication subsystem 1630 may include a means for transmitting or receiving data, such as identifiers of HMD devices, position data, a geographic map, a heat map, photos, or videos, using antenna(s) 1634 and wireless link(s) 1632. Wireless communication subsystem 1630, processor(s) 1610, and memory 1620 may together comprise at least a part of one or more of a means for performing some functions disclosed herein.

Embodiments of electronic system 1600 may also include one or more sensors 1690. Sensor(s) 1690 may include, for example, an image sensor, an accelerometer, a pressure sensor, a temperature sensor, a proximity sensor, a magnetometer, a gyroscope, an inertial sensor (e.g., a module that combines an accelerometer and a gyroscope), an ambient light sensor, or any other similar module operable to provide sensory output and/or receive sensory input, such as a depth sensor or a position sensor. For example, in some implementations, sensor(s) 1690 may include one or more inertial measurement units (IMUs) and/or one or more position sensors. An IMU may generate calibration data indicating an estimated position of the HMD device relative to an initial position of the HMD device, based on measurement signals received from one or more of the position sensors. A position sensor may generate one or more measurement signals in response to motion of the HMD device. Examples of the position sensors may include, but are not limited to, one or more accelerometers, one or more gyroscopes, one or more magnetometers, another suitable type of sensor that detects motion, a type of sensor used for error correction of the IMU, or any combination thereof. The position sensors may be located external to the IMU, internal to the IMU, or any combination thereof. At least some sensors may use a structured light pattern for sensing.

Electronic system 1600 may include a display module 1660. Display module 1660 may be a near-eye display, and may graphically present information, such as images, videos, and various instructions, from electronic system 1600 to a user. Such information may be derived from one or more application modules 1622-1624, virtual reality engine 1626, one or more other hardware modules 1680, a combination thereof, or any other suitable means for resolving graphical content for the user (e.g., by operating system 1625). Display module 1660 may use LCD technology, LED technology (including, for example, OLED, ILED, μ-LED, AMOLED, TOLED, etc.), light emitting polymer display (LPD) technology, or some other display technology.

Electronic system 1600 may include a user input/output module 1670. User input/output module 1670 may allow a user to send action requests to electronic system 1600. An action request may be a request to perform a particular action. For example, an action request may be to start or end an application or to perform a particular action within the application. User input/output module 1670 may include one or more input devices. Example input devices may include a touchscreen, a touch pad, microphone(s), button(s), dial(s), switch(es), a keyboard, a mouse, a game controller, or any other suitable device for receiving action requests and communicating the received action requests to electronic system 1600. In some embodiments, user input/output module 1670 may provide haptic feedback to the user in accordance with instructions received from electronic system 1600. For example, the haptic feedback may be provided when an action request is received or has been performed.

Electronic system 1600 may include a camera 1650 that may be used to take photos or videos of a user, for example, for tracking the user's eye position. Camera 1650 may also be used to take photos or videos of the environment, for example, for VR, AR, or MR applications. Camera 1650 may include, for example, a complementary metal-oxide-semiconductor (CMOS) image sensor with a few millions or tens of millions of pixels. In some implementations, camera 1650 may include two or more cameras that may be used to capture 3-D images.

In some embodiments, electronic system 1600 may include a plurality of other hardware modules 1680. Each of other hardware modules 1680 may be a physical module within electronic system 1600. While each of other hardware modules 1680 may be permanently configured as a structure, some of other hardware modules 1680 may be temporarily configured to perform specific functions or temporarily activated. Examples of other hardware modules 1680 may include, for example, an audio output and/or input module (e.g., a microphone or speaker), a near field communication (NFC) module, a rechargeable battery, a battery management system, a wired/wireless battery charging system, etc. In some embodiments, one or more functions of other hardware modules 1680 may be implemented in software.

In some embodiments, memory 1620 of electronic system 1600 may also store a virtual reality engine 1626. Virtual reality engine 1626 may execute applications within electronic system 1600 and receive position information, acceleration information, velocity information, predicted future positions, or any combination thereof of the HMD device from the various sensors. In some embodiments, the information received by virtual reality engine 1626 may be used for producing a signal (e.g., display instructions) to display module 1660. For example, if the received information indicates that the user has looked to the left, virtual reality engine 1626 may generate content for the HMD device that mirrors the user's movement in a virtual environment. Additionally, virtual reality engine 1626 may perform an action within an application in response to an action request received from user input/output module 1670 and provide feedback to the user. The provided feedback may be visual, audible, or haptic feedback. In some implementations, processor(s) 1610 may include one or more GPUs that may execute virtual reality engine 1626.

In various implementations, the above-described hardware and modules may be implemented on a single device or on multiple devices that can communicate with one another using wired or wireless connections. For example, in some implementations, some components or modules, such as GPUs, virtual reality engine 1626, and applications (e.g., tracking application), may be implemented on a console separate from the head-mounted display device. In some implementations, one console may be connected to or support more than one HMD.

In alternative configurations, different and/or additional components may be included in electronic system 1600. Similarly, functionality of one or more of the components can be distributed among the components in a manner different from the manner described above. For example, in some embodiments, electronic system 1600 may be modified to include other system environments, such as an AR system environment and/or an MR environment.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments were described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, AB, AC, BC, AA, ABC, AAB, AABBCCC, etc.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory memory medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto without departing from the broader spirit and scope as set forth in the claims. Thus, although specific embodiments have been described, these are not intended to be limiting. Various modifications and equivalents are within the scope of the following claims.

What is claimed is:

1. A semiconductor wafer comprising:
a silicon substrate;
a GaP buffer layer grown on the silicon substrate;
a first doped GaP contact layer on the GaP buffer layer;
an active region including:
a plurality of InGaP quantum barrier layers; and
one or more InGaAsP quantum well layers, each of the one or more InGaAsP quantum well layers being sandwiched by two InGaP quantum barrier layers of the plurality of InGaP quantum barrier layers; and
a second doped GaP contact layer on the active region.

2. The semiconductor wafer of claim 1, further comprising:
a first doped AlGaP cladding layer between the first doped GaP contact layer and the active region; and
a second doped AlGaP cladding layer between the second doped GaP contact layer and the active region.

3. The semiconductor wafer of claim 2, wherein:
the first doped AlGaP cladding layer is characterized by a composition of AlₓGa₁₋ₓP with 0<x≤0.5 and a thickness between 50 and 2000 nm; and
the second doped AlGaP cladding layer is characterized by a composition of AlₓGa₁₋ₓP with 0<x≤0.5 and a thickness between 50 and 2000 nm.

4. The semiconductor wafer of claim 1, further comprising an etch-stop layer between the first doped GaP contact layer and the GaP buffer layer.

5. The semiconductor wafer of claim 4, wherein the etch-stop layer is characterized by:
a composition of AlₓGa₁₋ₓP with 0<x≤0.5;
a thickness between 0 and 1000 nm; and
a dopant density between 1×10¹⁸ and 20×10¹⁸ cm⁻³, wherein the etch-stop layer is p-doped or n-doped.

6. The semiconductor wafer of claim 1, wherein the silicon substrate has a diameter greater than 6 inches.

7. The semiconductor wafer of claim 1, wherein the GaP buffer layer is characterized by:
a thickness between 100 and 3000 nm; and
a dopant density between 1×10¹⁸ and 20×10¹⁸ cm⁻³,
wherein the GaP buffer layer is p-doped with C, Mg, Zn, Be, or a combination thereof.

8. The semiconductor wafer of claim 1, wherein the first doped GaP contact layer is characterized by:
a thickness between 10 and 500 nm; and
a dopant density between 1×10¹⁹ and 20×10¹⁹ cm⁻³,
wherein the first doped GaP contact layer is p-doped with C, Mg, Zn, Be, or a combination thereof.

9. The semiconductor wafer of claim 1, wherein each of the plurality of InGaP quantum barrier layers is characterized by:
a composition of InₓGa₁₋ₓP with 0<x≤0.2;
a thickness between 0 and 500 nm; and
undoped or doped with C, Mg, Zn, Be, Si, Ge, S, Se, Te, or a combination thereof at a dopant density between 1×10¹⁶ and 50×10¹⁶ cm⁻³.

10. The semiconductor wafer of claim 1, wherein each of the one or more InGaAsP quantum well layers is characterized by:
a composition of InₓGa₁₋ₓAs_{y}P_{1-y} with 0<x≤0.55 and 0<y≤0.3;
a thickness between 2 and 10 nm; and
undoped or doped with C, Mg, Zn, Be, Si, Ge, S, Se, Te, or a combination thereof at a dopant density between 1×10¹⁵ and 50×10¹⁶ cm⁻³.

11. The semiconductor wafer of claim 1, wherein the second doped GaP contact layer is characterized by:
a thickness between 10 and 300 nm; and
a dopant density between 5×10¹⁸ and 50×10¹⁸ cm⁻³,
wherein the second doped GaP contact layer is n-doped with Si, S, Ge, Te, Se, or a combination thereof.

12. A light source comprising:
a silicon substrate;
a GaP buffer layer on the silicon substrate; and
a plurality of mesa structures on the GaP buffer layer, each of the plurality of mesa structures including:
a first doped GaP contact layer on the GaP buffer layer;
an active region including:
a plurality of InGaP quantum barrier layers; and
one or more InGaAsP quantum well layers, each of the one or more InGaAsP quantum well layers being sandwiched by two InGaP quantum barrier layers of the plurality of InGaP quantum barrier layers; and
a second doped GaP contact layer on the active region.

13. The light source of claim 12, wherein each of the plurality of mesa structures includes:
a first doped AlGaP cladding layer between the first doped GaP contact layer and the active region, the first doped AlGaP cladding layer characterized by a composition of AlₓGa₁₋ₓP with 0<x≤0.5; and
a second doped AlGaP cladding layer between the second doped GaP contact layer and the active region, the second doped AlGaP cladding layer characterized by a composition of AlₓGa₁₋ₓwith 0<x≤0.5.

14. The light source of claim 12, further comprising an etch-stop layer between the GaP buffer layer and the first doped GaP contact layer of each of the plurality of mesa structures, the etch-stop layer characterized a composition of AlₓGa₁₋ₓP with 0<x≤0.5.

15. The light source of claim 12, wherein:
each of the plurality of InGaP quantum barrier layers is characterized by a composition of InₓGa₁₋ₓP with 0<x≤0.2 and a thickness between 0 and 500 nm; and
each of the one or more InGaAsP quantum well layers is characterized by a composition of InₓGa₁₋ₓAs_{y}P_{1-y} with 0<x≤0.55 and 0<y≤0.3 and a thickness between 2 and 10 nm.

16. The light source of claim 12, wherein the silicon substrate has a diameter greater than 6 inches.

17. A micro-light emitting diode (micro-LED) device comprising:
a silicon backplane including drive circuits formed thereon; and
an array of micro-LEDs bonded to the silicon backplane, wherein each micro-LED of the array of micro-LEDs includes:
a first doped GaP contact layer;
an active region including:
a plurality of InGaP quantum barrier layers; and
one or more InGaAsP quantum well layers, wherein each of the one or more InGaAsP quantum well layers is sandwiched by two InGaP quantum barrier layers of the plurality of InGaP quantum barrier layers and is configured to emit red light; and
a second doped GaP contact layer on the active region.

18. The micro-LED device of claim 17, wherein:
each of the plurality of InGaP quantum barrier layers is characterized by a composition of InₓGa₁₋ₓP with 0<x≤0.2 and a thickness between 0 and 500 nm; and
each of the one or more InGaAsP quantum well layers is characterized by a composition of InₓGa₁₋ₓAs_{y}P_{1-y} with 0<x≤0.55 and 0<y≤0.3 and a thickness between 2 and 10 nm.

19. The micro-LED device of claim 17, further comprising:
a first doped AlGaP cladding layer between the first doped GaP contact layer and the active region; and
a second doped AlGaP cladding layer between the second doped GaP contact layer and the active region.

20. The micro-LED device of claim 17, wherein:
the first doped GaP contact layer is characterized by:
a thickness between 10 and 300 nm; and
a dopant density between 5×10¹⁸ and 50×10¹⁸ cm⁻³,
wherein the first doped GaP contact layer is n-doped with Si, S, Ge, Te, Se, or a combination thereof; and
the second doped GaP contact layer is characterized by:
a thickness between 10 and 500 nm; and
a dopant density between 1×10¹⁹ and 20×10¹⁹ cm⁻³,
wherein the second doped GaP contact layer is p-doped with C, Mg, Zn, Be, or a combination thereof.
